(19) United States
(12) Patent Application Publication
(10) Pub. No.: US 2018/0072028 A1
(43) Pub. Date: Mar. 15, 2018

(54) HARDCOAT FILM, FRONT PLATE OF IMAGE DISPLAY ELEMENT, RESISTIVE FILM-TYPE TOUCH PANEL, CAPACITANCE-TYPE TOUCH PANEL, AND IMAGE DISPLAY

(71) Applicant: FUJIFILM Corporation, Tokyo (JP)

(72) Inventors: Keigo UEKI, Kanagawa (JP); Katsuyuki TAKADA, Kanagawa (JP); Yuuichi FUKUSHIGE, Kanagawa (JP)

(73) Assignee: FUJIFILM Corporation, Tokyo (JP)

(21) Appl. No.: 15/812,378

(22) Filed: Nov. 14, 2017

Related U.S. Application Data
(63) Continuation of application No. PCT/JP2016/066318, filed on Jun. 2, 2016.

(30) Foreign Application Priority Data
Jun. 2, 2015 (JP) 2015-112427

(51) Int. Cl. B32B 27/16; B32B 27/20; B32B 27/30; G06F 3/044; G06F 3/045; C08J 7/04; G02F 1/1335; H01L 51/50; H05B 33/02

(52) U.S. Cl. CPC B32B 27/16; B32B 27/20; B32B 27/308; G06F 3/044; G06F 3/045; B32B 27/302; G02F 1/1335; H01L 51/50; H05B 33/02; B32B 27/306; C08J 7/04

(57) ABSTRACT

A hardcoat film includes a base material film and a cured layer disposed on at least one surface of the base material film, in which the cured layer is obtained by curing an active energy ray-curable resin composition, a film thickness of the cured layer is greater than 10 μm, and contains polyrotaxane, inorganic fine particles having an average primary particle diameter of less than 2 μm, and particles having an average primary particle diameter of equal to or greater than 2 μm, and a mass of the particles is equal to or greater than 0.10 g/cm³. In the hardcoat film, both high surface hardness and sufficient surface asperities can be achieved in the cured layer having a large film thickness containing the inorganic fine particles. Also provided are a front plate of an image display element, a resistive film-type touch panel, a capacitance-type touch panel, and an image display.

### CROSS-REFERENCE TO RELATED APPLICATIONS

This application is a Continuation of PCT International Application No. PCT/JP2016/06631.8, filed on Jun. 2, 2016, which claims priority under 35 U.S.C. Section 119(a) to Japanese Patent Application No, 2015-112427 filed on Jun. 2, 2015. Each of the above applications is hereby expressly incorporated by reference, in its entirety, into the present application.

### BACKGROUND OF THE INVENTION

### 1. Field of the Invention

The present invention relates to a hardcoat film, a front plate of an image display element, a resistive film-type touch panel, a capacitance-type touch panel, and an image display. Specifically, the present invention relates to a hardcoat film and a front plate of an image display element, a resistive film-type touch panel, a capacitance-type touch panel, and an image display in which the hardcoat film is used.

### 2. Description of the Related Art

In the related art, for the uses in which high durability is required for a front plate of an image display or a substrate of a touch panel, glass such as chemical strengthening glass is mainly used. Compared to the glass, plastic has advantages of being lightweight, having excellent workability, being inexpensive, and having excellent transparency. Therefore, in recent years, in the uses in which glass is mainly utilized, the usefulness of plastic as a material substituting glass has drawn attention. Under these circumstances, for example, JP2003-l47017A describes that in a case where a curable composition is used which contains both the cross-linkable polymer containing a repeating unit having a specific structure and the compound containing two or more ethylenically unsaturated groups in the same molecule and is cured by polymerizing both the ring-opening polymerizable group and the ethylenically unsaturated group in the cross-linkable polymer, a cured substance is obtained which has high hardness and less undergoes cure shrinkage. Furthermore, JP2003-147017A describes that a hardcoat film is used as a protect film for an image display or a touch panel; cross-linked inorganic fine particles are generally hard, and in a case where a cured layer is filled with such particles, the surface hardness of the cured layer can be improved; and by increasing the film thickness of a cured layer, the hardness is increased, and the effect of making it difficult for cracking or film peeling to occur is obtained.

### SUMMARY OF THE INVENTION

However, unfortunately, the surface asperities of the hardcoat film described in JP2003-147017A are too small. It is hard to say that a touch panel, in which the hardcoat film described in JP2003-147017A having too small surface asperities is used, gives a pleasant feeling of writing, although the reason is unclear. As one of the reasons, for example, in a case where the surface asperities of the hardcoat film are too small, sliding properties becomes an issue at the time of operating the touch panel by using a stylus or a finger. In this way, it is understood that in a case where the film thickness of a cured layer of the hardcoat film of the related art is increased, and the pencil hardness of the hardcoat film is increased by adding inorganic fine particles, a surface roughness at which a pleasant feeling of wiring is obtained cannot be sufficiently expressed.

An object of the present invention is to provide a hardcoat film in which both the high surface hardness and the sufficient surface asperities can be achieved in a thick cured layer containing inorganic fine particles.

The inventors of the present invention added matt particles having an average primary particle diameter of about several micrometers to a thin cured layer having a film thickness of equal to or smaller than 10 μm. As a result, the inventors understood that surface asperities can be formed due to the shape of the matt particles on the surface of the thin cured layer.

Therefore, the inventors of the present invention considered that by adding matt particles to a thick cured layer containing inorganic fine particles, it will be possible to form surface asperities with maintaining high hardness and to improve the sliding properties at the time of performing writing by using a stylus, and performed an examination. However, even though matt particles were added to the thick cured layer containing inorganic fine particles, surface asperities were not formed.

In contrast, in a case where matt particles were added to the thick cured layer not containing inorganic fine particles, surface asperities could be formed.

These results of the examination do not clearly show why the surface asperities were not formed even though matt particles were added to the thick cured layer containing inorganic fine particles.

Under the circumstances in which why the surface asperities were not formed even though matt particles were added to the thick cured layer containing inorganic fine particles was not clarified, regarding whether surface asperities can be made in a case where various additives are added to the thick cured layer containing inorganic fine particles, the inventors of the present invention performed an intensive examination by carrying out numerous experiments. As a result, the inventors understood that by adding polyrotaxane to the cured layer in addition to the matt particles having a specific average primary particle diameter, even in a case where the film thickness of the cured layer is increased and the pencil hardness is increase by adding inorganic fine particles, the surface roughness can be sufficiently expressed. That is, the inventors have found that it is possible to provide a hardcoat film in which both the high surface hardness and the sufficient surface asperities can be achieved in thick cured layer containing inorganic fine particles, and accomplished the present invention.

The present invention, which is means for achieving the aforementioned object, and preferred constitutions of the present invention are as described below.

[1] A hardcoat film comprising a base material film, and a cured layer disposed on at least one surface of the base material film, in which the cured layer is obtained by curing an active energy ray-curable resin composition, a film thickness of the cured layer is greater than 10 μm, the cured layer contains polyrotaxane, inorganic fine particles having an average primary particle diameter of less than 2 μm, and matt particles having an average primary particle diameter of equal to or greater than 2 μm, and a mass of the matt particles contained in the cured layer is equal to or greater than 0.10 g/cm³.

[2] The hardcoat film described in [1], in which the film thickness of the cured layer is preferably greater than 10 μm and equal to or smaller than 60 μm.

[3] The hardcoat film described in [1] or [2], in which the polyrotaxane preferably has an unsaturated double bond group.

[4] The hardcoat film described in [3], in which the unsaturated double bond group is preferably a methacryloyl group.

[5] The hardcoat film described in any one of [1] to [4], in which a weight-average molecular weight of the polyrotaxane is preferably equal to or smaller than 600,000.

[6] The hardcoat film described in any one of [1] to [5], in which the matt particles are preferably organic resin particles.

[7] The hardcoat film described in any one of [1] to [6], preferably further comprising a layer of low refractive index on the cured layer directly or through another layer.

[8] The hardcoat film described in any one of [1] to [7], in which the base material film is preferably a laminated film having at least one layer of acrylic resin film and at least one layer of polycarbonate-based resin film.

[9] The hardcoat film described in any one of [1] to [7], in which the base material film is preferably a cellulose acylate film.

[10] The hardcoat film described in any one of [1] to [9], in which a film thickness of the base material film is preferably equal to or greater than 100 μm.

[11] The hardcoat film described in any one of [1] to [10], preferably further comprising a touch sensor film on a surface of the base material film that is opposite to a surface of the base material film on which the cured layer is disposed.

[12] The hardcoat film described in any one of [1] to [11], which preferably further comprising a polarizer on a surface of the base material film that is opposite to a surface of the base material film on which the cured layer is disposed.

[13] The hardcoat film described in any one of [1] to [12] that is preferably a hardcoat film for a front plate of a touch panel.

[14] A front plate of an image display element, comprising the hardcoat film described in any one of [1] to [13].

[15] A resistive film-type touch panel comprising the front plate of an image display element described in [14].

[16] A capacitance-type touch panel comprising the front plate of an image display element described in [14].

[17] An image display comprising the front plate of an image display element described in [14] and an image display element.

[18] The image display described in [17], in which the image display element is preferably a liquid crystal display element.

[19] The image display described in [17], in which the image display element is preferably an organic electroluminescence display element.

[20] The image display described in any one of [17] to [19], in which the image display element is preferably an in-cell touch panel display element.

[21] The image display described in any one of [17] to [19], in which the image display element is preferably an on-cell touch panel display element.

### DESCRIPTION OF THE PREFERRED EMBODIMENTS

Hereinafter, the present invention will be specifically described. The following constituents will be described based on typical embodiments or specific examples in some cases, but the present invention is not limited to the embodiments. In the present specification, a range of numerical values described using “to” means a range which includes the numerical values listed before and after “to” as a lower limit and an upper limit respectively.

[Hardcoat Film]

The hardcoat film of the present invention is a hardcoat film having a base material film and a cured layer disposed on at least one surface of the base material film, in which the cured layer is obtained by curing an active energy ray-curable resin composition, a film thickness of the cured layer is greater than 10 μm, the cured layer contains polyrotaxane, inorganic fine particles having an average primary particle diameter of less than 2 μm, and matt particles having an average primary particle diameter of equal to or greater than 2 μm, and a mass of the matt particles contained in the cured layer is 0.10 g/cm³.

Because the hardcoat film of the present invention has the aforementioned constitution, the hardcoat film brings about an effect of being able to achieve both the high surface hardness and the sufficient surface asperities in the thick cured layer containing inorganic fine particles. Here, the mechanism is unclear which enables both the high surface hardness and the sufficient surface asperities to be achieved in the thick cured layer containing inorganic fine particles by the aforementioned constitution, and the effects of the present invention are effects that cannot be predicted from the knowledge of the related art.

Hereinbelow, preferred aspects of the hardcoat film of the present invention will be described.

<Base Material Film>

The base material film may be a single-layered film consisting of one resin layer or a laminated film consisting of two or more resin layers. “Resin” includes an oligomer, a prepolymer, and a polymer in meaning.

The base material film is available as a commercial product or can be manufactured by a known film forming method. As the commercial base material film, for example, it is possible to use TECHNOLOGY C101 and TECHNOLOGY C001 (manufactured by Escarbo Sheet Company, Ltd.), AW-10 (manufactured by Wavelock Advanced Technology Co., Ltd.), and the like.

Examples of resin films that can be used as the base material film include an acrylic resin film, a polycarbonate-based resin film, a triacetyl cellulose (TAC)-based resin film, a polyolefin-based resin film, a polyester-based resin film, an acrylonitrile-butadiene-styrene copolymer film, and the like.

In a preferred aspect, a resin film that can be used as the base material film is at least one kind of film selected from the group consisting of an acrylic resin film and a polycarbonate-based resin film.

In a preferred aspect, the resin film contained in the base material is a laminated film having two or more layers of resin films. The number of films laminated is not particularly limited but is preferably 2 or 3. In the hardcoat film of the present invention, the base material film is preferably a laminated film having at least one layer of acrylic resin film and at least one layer of polycarbonate-based resin film. As an example of a more preferred base material film (laminated film), a laminated film can be exemplified which has an acrylic resin film, a polycarbonate-based resin film, and an acrylic resin film in this order. The acrylic resin film refers to a resin film of a polymer or a copolymer containing one or more kinds of monomers selected from the group consisting of an acrylic acid ester and a methacrylic acid ester. Examples of the acrylic resin film include a polymethyl methacrylate (PMMA) film.

(Optional Component of Base Material Film)

The base material film can also contain one or more kinds of optional components as other components such as known additives in addition to a resin. As an example of the components that can be optionally contained in the base material film, an ultraviolet absorber can be exemplified. Examples of the ultraviolet absorber include a benzotriazole compound and a triazine compound. The benzotriazole compound is a compound having a benzotriazole ring, and specific examples thereof include various benzotriazole-based ultraviolet absorbers described in paragraph “0033” in JP2013-111835A. The triazine compound is a compound having a triazine ring, and specific examples thereof include various triazine-based ultraviolet absorbers described in paragraph “0033” in JP2013-111835A. The mass of the ultraviolet absorber contained in the resin film is, for example, about 0.1 to 10 parts by mass with respect to 100 parts by mass of the resin contained in the film, but is not particularly limited. Regarding the ultraviolet absorber, paragraph “0032” in JP2013-111835A can also be referred to. In the present invention and the present specification, ultraviolet rays mean the light having a central emission wavelength in a wavelength range of 200 to 380 nm.

(Film Thickness of Base Material Film)

From the viewpoint of increasing pencil hardness, the film thickness of the base material film in the hardcoat film of the present invention is preferably equal to or greater than 100 μm, more preferably 100 to 1,000 μm, particularly preferably 150 to 500 μm, and more particularly preferably 200 to 500 μm.

<Cured Layer>

The hardcoat film of the present invention has a cured layer which is disposed on at least one surface of the base material film. The cured layer is obtained by curing an active energy ray-curable resin composition. The film thickness of the cured layer is greater than 10 μm. The cured layer contains polyrotaxane, inorganic fine particles having an average primary particle diameter of less than 2 μm, and matt particles having an average primary particle diameter of equal to or greater than 2 μm. The mass of the matt particles contained in the cured layer is equal to or greater than 0.10 g/cm³.

In the present invention, the cured layer refers to a layer having a pencil hardness of equal to or higher than 2H which is measured on the surface of the cured layer. Here, because the hardcoat film of the present invention can achieve both the high surface hardness and the sufficient surface asperities, the pencil hardness of the cured layer is preferably equal to or higher than 5H.

(Constitution of Cured Layer)

The cured layer may be constituted with a plurality of (two or more) layers. In this case, among the plurality of cured layers, one cured layer or two or more cured layers may satisfy the conditions of “the cured layer is obtained by curing an active energy ray-curable resin composition; the film thickness of the cured layer is greater than 10 μm; the cured layer contains polyrotaxane, inorganic fine particles having an average primary particle diameter of less than 2 μm, and matt particles having an average primary particle diameter of equal to or greater than 2 μm; and the mass of the matt particles contained in the cured layer is equal to or greater than 0.10 g/cm³”. It is preferable that any one of the cured layers satisfies the aforementioned conditions. From the viewpoint of achieving both the pencil hardness and the surface roughness, the cured layer satisfying the aforementioned conditions is more preferably a layer disposed on the farthest side from the base material film.

In the hardcoat film of the present invention, the film thickness of the cured layer is greater than 10 μm. From the viewpoint of increasing pencil hardness, it is preferable that the cured layer has a large film thickness. In contrast, from the viewpoint of increasing surface roughness, it is preferable that the film thickness of the cured layer is somewhat small. The film thickness of the cured layer is preferably greater than 10 μm and equal to or smaller than 60 μm, preferably 15 to 50 μm, more preferably 15 to 40 μm, and particularly preferably 15 to 30 μm.

(Active Energy Ray-Curable Resin Composition)

The active energy ray-curable resin composition is a composition which can form a cured layer by being subjected to an active energy ray irradiation treatment.

As a preferred aspect of the active energy ray-curable resin composition for forming the cured layer, an active energy ray-curable resin composition can be exemplified which contains polyrotaxane, inorganic, fine particles having an primary particle diameter of less than 2 μm, and matt particles having an average primary particle diameter of equal to or greater than 2 μm. As a more preferred aspect, an active energy ray-curable resin composition can be exemplified which further contains one kind of polymerizable compound. As a particularly preferred aspect, an active energy ray-curable resin composition can be exemplified which further contains a radically polymerizable compound containing two or more radically polymerizable groups selected from the group consisting of an acryloyl group and a methacryloyl group in one molecule and containing one or more urethane bonds in one molecule, a cationically polymerizable compound, a radical photopolymerization initiator, and a cationic photopolymerization initiator.

The active energy ray-curable resin composition and the cured layer obtained by curing the active energy ray-curable resin composition will be more specifically described, but the present invention is not limited to the aspects described below.

The aforementioned cured layer can also be formed by using various other active energy ray-curable resin compositions that are generally used for forming a cured layer.

(Method for Manufacturing Active Energy Ray-Curable Resin Composition or Cured Layer)

The active energy ray-curable resin composition can be prepared by simultaneously mixing various components together or sequentially mixing various components together in any order. The preparation method is not particularly limited, and for preparing the composition, a known stirrer and the like can be used.

The active energy ray-curable resin composition can be used for forming a cured layer by coating the base material film with the composition directly or through another layer such as an adhesive layer or a pressure sensitive adhesive layer and irradiating the composition with light. The coating may be performed by known coating methods such as a dip coating method, an air knife coating method, a curtain coating method, a roller coating method, a die coating method, a wire bar coating method, and a gravure coating method. The amount of the composition used for coating may be adjusted such that a cured layer having a desired film thickness can be formed. The cured layer can also be formed as a cured layer having a laminated structure including two or more layers (for example, about two to five layers) by simultaneously or sequentially coating the base material film with two or more kinds of compositions having different makeups.

By irradiating the active energy ray-curable resin composition, with which the base material film is coated, with active energy rays, the cured layer can be formed. For example, in a case where the active energy ray-curable resin composition has a radically polymerizable compound and a cationically polymerizable compound, it is preferable that a polymerization reaction between the radically polymerizable compound and the cationically polymerizable compound is initiated and proceeds by the influence of a radical photopolymerization initiator and a cationic photopolymerization initiator respectively. The wavelength of light radiated may be determined according to the type of the polymerizable compound and the polymerization initiator used. Examples of light sources for light irradiation include a high-pressure mercury lamp, an ultrahigh-pressure mercury lamp, a carbon arc lamp, a metal halide lamp, a xenon lamp, a chemical lamp, an electrodeless discharge lamp, a light emitting diode (LED), and the like that emit light in a wavelength range of 150 to 450 nm. The light irradiation amount is generally within a range of 30 to 3,000 mJ/cm², and preferably within a range of 100 to 1,500 mJ/cm². If necessary, a drying treatment may be performed before or after the light irradiation or before and after the light irradiation. The drying treatment can be performed by hot air blowing, disposing the base material film with the composition in a heating furnace, or transporting the base material film with the composition in a heating furnace, and the like. The heating temperature may be set to be a temperature at which a solvent can be dried and removed, and is not particularly limited. Herein, the heating temperature refers to the temperature of hot air or the internal atmospheric temperature of the heating furnace.

(Polyrotaxane)

Polyrotaxane is obtained by disposing a blocking group on both terminals (both terminals of a linear molecule) of pseudo-polyrotaxane, in which an opening portion of each cyclic molecule is penetrated by a linear molecule in the form of a skewer and the linear molecule is included in a plurality of cyclic molecules, such that the cyclic molecules are not liberated.

In the hardcoat film of the present invention, the weight-average molecular weight of the polyrotaxane is preferably equal to or smaller than 1,000,000 from the viewpoint of increasing pencil hardness, more preferably equal to or smaller than 600,000, and particularly preferably 600,000 to 180,000.

—Linear Molecule—

The linear molecule contained in the polyrotaxane is a molecule or a substance which is included in cyclic molecules and can be integrated by non-covalent bonding interaction. The linear molecule is not particularly limited, as long as it is linear. In the present invention, “linear molecule” refers to a molecule including a polymer and to all the substances satisfying the aforementioned requirements.

In the present invention, “linear” in “linear molecule” means that the molecule is substantially “linear”. That is, in a case where the cyclic molecule which is a rotator can rotate or the cyclic molecule can slide or move on the linear molecule, the linear molecule may have a branched chain. The length of the “linear” molecule is not particularly limited as long as the cyclic molecule can slide or move on the linear molecule.

Examples of the linear molecule of the polyrotaxane include hydrophilic polymers such as polyvinyl alcohol, polyvinyl pyrrolidone, poly(meth)acrylic acid, a cellulose-based resin (carboxymethyl cellulose, hydroxyethyl cellulose, hydroxypropyl cellulose, or the like), polyacrylamide, polyethylene oxide, polyethylene glycol, a polyvinyl acetal-based resin, polyvinyl methyl ether, polyamine, polyethyleneimine, casein, gelatin, starch, and/or a copolymer of these; hydrophobic polymers such as a polyolefin-based resin including polyethylene, polypropylene, or a copolymer resin with other olefin-based monomers, a polyester resin, a polyvinyl chloride resin, a polystyrene-based resin such as polystyrene or an acrylonitrile-styrene copolymer resin, an acrylic resin such as polymethyl methacrylate, a (meth)acrylic acid ester copolymer, or an acrylonitrile-methyl acrylate copolymer resin, a polycarbonate-based resin, a polyurethane resin, a vinyl chloride-vinyl acetate copolymer resin, and a polyvinyl butyral resin; and derivatives or modified substances of these.

The linear molecule is preferably a hydrophilic polymer. In a case where hygroscopicity is imparted to the cured layer, particularly, in a case where the base material is a cellulose acylate film, it is possible to suppress curling resulting from a difference in a coefficient of hygroscopic expansion between the cured layer and the base material film.

Among hydrophilic polymers, polyethylene glycol, polypropylene glycol, a polyethylene glycol-polypropylene glycol copolymer, polyisoprene, polyisobutylene, polybutadiene, polytetrahydrofuran, polydimethylsiloxane, polyethylene, and polypropylene are preferable, polyethylene glycol, polypropylene glycol, and a polyethylene glycol-polypropylene glycol copolymer are more preferable, and polyethylene glycol is particularly preferable.

It is preferable that the linear molecule of the polyrotaxane has a high breaking strength. Although the breaking strength of the hardcoat film layer also results from other factors such as a bonding strength between the blocking group and the linear molecule, a bonding strength between the cyclic molecule and a binder of the cured layer, and a bonding strength between the cyclic molecules, in a case where the linear molecule of the polyrotaxane has a high breaking strength, a higher breaking strength can be provided.

The molecular weight of the linear molecule of the polyrotaxane is preferably equal to or greater than 1,000 (for example, 1,000 to 1,000,000), more preferably equal to or greater than 5,000 (for example, 5,000 to 1,000,000 or 5,000 to 500,000), and particularly preferably equal to or greater than 10,000 (for example, 10,000 to 1,000,000, 10,000 to 500,000, or 10,000 to 300,000).

In view of “eco-friendliness”, the linear molecule of the polyrotaxane is preferably a biodegradable molecule.

It is preferable that the linear molecule of the polyrotaxane has a reactive group on both terminals thereof. By having the reactive group, the linear molecule can easily react with the blocking group. The type of the reactive group depends on the blocking group used, and the examples thereof include a hydroxyl group, an amino group, a carboxyl group, a thiol group, and the like.

—Cyclic Structure—

Any cyclic molecule can be used as the cyclic molecule of the polyrotaxane as long as it is a cyclic molecule which can include the aforementioned linear molecule.

In the present invention, “cyclic molecule” refers to various cyclic substances including a cyclic molecule. Furthermore, in the present invention, “cyclic molecule” refers to a molecule or substance that is substantially cyclic. That is, “substantially cyclic” means a molecule or substance that is not in the form of a completely closed ring similarly to the alphabet “C” and has a spiral structure in which one end and the other end of the alphabet “C” are superposed without being bonded to each other. Regarding a ring of “bicyclo molecule” which will be described later, the definition of “substantially cyclic” for “cyclic molecule” can also be applied. That is, either or both of the rings of “bicyclo molecule” may have a structure in which the ring is not in the form of a completely closed ring similarly to the alphabet “C” or have a spiral structure in which one end and the other end of the alphabet “C” are superposed (without being bonded to each other).

Examples of the cyclic molecule of the polyrotaxane include various cyclodextrins (for example, α-cyclodextrin, β-cyclodextrin, γ-cyclodextrin, dimethyl cyclodextrin, glucosyl cyclodextrin, and derivatives or modified substances of these), crown ethers, benzo crowns, dibenzo crowns, dicyclohexano crowns, and derivatives or modified substances of these.

The size of the opening portion of the cyclic molecule of the cyclodextrins, the crown ethers, and the like described above varies with the type of the cyclodextrins, the crown ethers, and the like. Accordingly, in a case where the type of the linear molecule used, specifically, in a case where the linear molecule used is regarded as having a cylindrical shape, according to the diameter of a cross-section of the cylinder, the hydrophobicity or hydrophilicity of the linear molecule, and the like, the cyclic molecule to be used can be selected. Furthermore, in a case where a cyclic molecule having a relatively large opening portion and a cylindrical linear molecule having a relatively small diameter are used, two or more linear molecules may be included in the opening portion of the cyclic molecule. Among the above cyclic molecules, cyclodextrins are preferable owing to “eco-friendliness” described above resulting from the biodegradability that they have.

It is preferable to use α-cyclodextrin as a cyclic molecule.

In a case where cyclodextrin is used as a cyclic molecule, provided that a maximum inclusion amount is 1, the number (inclusion amount) of cyclic molecules including the linear molecule is preferably 0.05 to 0.60, more preferably 0.10 to 0.50, and particularly preferably 0.20 to 0.40. In a case where the inclusion amount is equal to or greater than 0.05, a pulley effect is sufficiently exhibited. In a case where the inclusion amount is equal to or smaller than 0.60, an aspect is not easily established in which cyclodextrins as cyclic molecules are disposed too densely and hence the mobility of the cyclodextrins deteriorates, and the insolubility of the cyclodextrins in an organic solvent is within an excellent range. Accordingly, the solubility of the obtained polyrotaxane in an organic solvent is also in an excellent range.

It is preferable that the cyclic molecule of the polyrotaxane has a reactive group on the outside of the ring. At the time of bonding or crosslinking the cyclic molecules to each other, it is easy to perform the reaction by using the reactive group. Examples of the reactive group include a hydroxyl group, an amino group, a carboxyl group, a thiol group, an aldehyde group, and the like, although the type of the reactive group also depends on a crosslinking agent used. Furthermore, at the time of performing a blocking reaction described above, it is preferable to use a group that does not react with the blocking group.

—Polyrotaxane Having Unsaturated Double Bond Group—

In view of pencil hardness, the polyrotaxane in the hardcoat film of the present invention preferably has an unsaturated bond group, and more preferably has an unsaturated double bond group.

The position in which the polyrotaxane has an unsaturated bond group is not particularly limited. For example, an unsaturated bond group can be introduced into a portion corresponding to the cyclic molecule. By the introduction of the group, the polyrotaxane can be polymerized with a monomer having an ethylenically unsaturated group.

The introduction of the unsaturated bond group can be performed by, for example, substituting at least a portion of the cyclic molecule having a hydroxyl group (—OH) such as cyclodextrin with an unsaturated bond group and preferably with an unsaturated double bond group.

Examples of the unsaturated bond group include an unsaturated double bond group such as an olefinyl group. Examples thereof include a (meth)acryloyl group, a vinyl ether group, a styryl group, and the like, but the present invention is not limited thereto. The (meth)acryloyl group represents an acryloyl group and a methacryloyl group. From the viewpoint of increasing pencil hardness, the unsaturated double bond group in the hardcoat film of the present invention is preferably a methacryloyl group.

The introduction of the unsaturated double bond group can be performed by using the methods exemplified below. Examples of the methods include a method of using the formation of a carbamoyl bond of an isocyanate compound or the like; a method of using the formation of an ester bond of a carboxylic acid compound, an acid chloride compound, an acid anhdyride, or the like; a method of using the formation of a silyl ether bond of a silane compound or the like; a method of using the formation of a carbonate bond of a chlorocarbonic acid compound or the like; and the like.

In a case where a (meth)acryloyl group is introduced as an unsaturated double bond group through a carbamoyl bond, the introduction of the (meth)acryloyl group is performed by dissolving the polyrotaxane in a dehydrating solvent such as dimethylsulfoxide or dimethylformamide and adding (meth)acryloylating agent having an isocyanate group. Furthermore, in a case where a (meth)acryloyl group is introduced through an ether bond or an ester bond, it is also possible to use a (meth)acryloylating agent having an active group such as a glycidyl group or acid chloride.

The step of substituting a hydroxyl group contained in the cyclic molecule with an unsaturated double bond group may be performed before, in the middle of, or after a step of preparing pseudo-polyrotaxane. Furthermore, the substituting step may be performed before, in the middle of, or after a step of preparing polyrotaxane by blocking the pseudo-polyrotaxane. In addition, in a case where the polyrotaxane is cross-linked polyrotaxane, the substituting step may be performed before, in the middle of, or after a step of crosslinking polyrotaxane molecules. The substituting step may also be performed at two or more stages among a stage before the aforementioned steps, a stage in the middle of the aforementioned steps, and a stage after the aforementioned steps. It is preferable that the substituting step is performed between the preparation of the polyrotaxane by blocking of the pseudo-polyrotaxane and the crosslinking of the polyrotaxane molecules. The conditions used in the substituting step depend on the unsaturated double bond group substituting the hydroxyl group, but are not particularly limited. It is possible to use various reaction methods and reaction conditions.

—Blocking Group—

Any group may be used as the blocking group of the polyrotaxane as long as the group maintains the shape in which the cyclic molecule is skewered by the linear molecule. Examples of such a group include a group having “bulkiness” and/or a group having “ionic properties” and the like. Herein, “group” means various groups including a molecular group and a polymer group. “Ionic properties” of the group having “ionic properties” and “ionic properties” of the cyclic molecule affect each other, for example, repel each other, and in this way, the shape in which the cyclic molecule is skewered by the linear molecule can be maintained.

The blocking group of the polyrotaxane may be a main chain or a side chain of a polymer as long as the skewered shape can be maintained as described above.

Specifically, examples of the blocking group as a molecular group include dinitrophenyl groups such as a 2,4-dinitrophenyl group and a 3,5-dinitrophenyl group, cyclodextrins, adamantane groups, trityl groups, fluoresceins, pyrenes, and derivatives or modified substances of these. More specifically, in a case where α-cyclodextrin is used as a cyclic molecule and polyethylene glycol is used as a linear molecule, examples of the blocking group as a molecular group include cyclodextrins, dinitrophenyl groups such as a 2,4-dinitrophenyl group and a 3,5-dinitrophenyl group, adamantane groups, trityl groups, fluoresceins, pyrenes, and derivatives or modified substances of these.

Next, modified polyrotaxane which can be preferably used in the present invention will be described.

In the present invention, it is possible to preferably use polyrotaxane obtained by adopting a plurality of modifications described below in combination.

—Cross-Linked Polyrotaxane—

Cross-linked polyrotaxane refers to a compound in which cyclic molecules of two or more polyrotaxane molecules are combined by a chemical bond. The two cyclic molecules may be the same as or different from each other. At this time, the chemical bond may be simply a bond or a bond formed through various atoms or molecules.

It is also possible to use a molecule containing a cyclic molecule that has a cross-linked cyclic structure, that is, “bicyclo molecule” having first and second rings. In this case, for example, by mixing “bicyclo molecule” with a linear molecule such that the linear molecule is included in the first and second rings of “bicyclo molecule” in the form of a skewer, cross-linked polyrotaxane can be obtained.

In the cross-linked polyrotaxane, the cyclic molecules penetrated by the linear molecule in the form of skewer can move along the linear shape (pulley effect). Accordingly, the cross-linked polyrotaxane has viscoelasticity, and even though tension is applied thereto, the tension is evenly dispersed due to the pulley effect, and as a result, the internal stress can. be relaxed.

—Hydrophobized Modified Polyrotaxane—

In a case where the cyclic molecule of the polyrotaxane is cyclodextrins such as α-cyclodextrin, in the present invention, hydrophobized modified polyrotaxane, which is obtained by substituting at least one of the hydroxyl groups of the cyclodextrin with other organic groups (hydrophobic groups), is more preferably used because the solubility of the hydrophobized modified polyrotaxane in a solvent contained in a composition for forming a hardcoat film layer is improved.

Specific examples of the hydrophobic groups include an alkyl group, a benzyl group, a benzene derivative-containing group, an acyl group, a silyl group, a trityl group, a nitric acid ester group, a tosyl group, an alkyl-substituted ethylenically unsaturated group as a photocuring moiety, an alkyl-substituted epoxy group as a thermosetting moiety, and the like. However, specific examples of the hydrophobic groups are not limited to the above. Furthermore, in the aforementioned hydrophobized modified polyrotaxane, one kind of hydrophobic group described above may be used singly, or two or more kinds thereof may be used in combination.

Provided that the maximum number of modifiable hydroxyl groups of cyclodextrin is 1, a degree of modification that shows a degree of modification with the aforementioned hydrophobic modification group is preferably equal to or higher than 0.02 (equal to or lower than 1), more preferably equal to or higher than 0.04, and even more preferably equal to or higher than 0.06.

In a case where the degree of modification is less than 0.02, the solubility in an organic solvent becomes insufficient, and hence an insoluble material (a projection portion resulting from the adherence of a foreign substance or the like) is generated in some cases.

The maximum number of modifiable hydroxyl groups of cyclodextrin is in other word the total number of hydroxyl groups contained in the cyclodextrin not yet being modified. The degree of modification is in other word a ratio of the number of modified hydroxyl groups to the total number of hydroxyl groups.

The number of hydrophobic modification groups may be at least 1, but in this case, it is preferable that one cyclodextrin ring has one hydrophobic modification group.

By the introduction of the hydrophobic modification group having a functional group, it is possible to improve the reactivity with respect to other polymers. Next, polyrotaxane having an unsaturated double bond group will be described, and the unsaturated double bond group functions as a hydrophobic modification group.

As commercially available polyrotaxane, it is possible to preferably use SeRM SUPER POLYMERS SH3400P, SH2400P, SH1310P, SM3405P, SM1315P, SA3405P, SA2405P, SA1315P, SH3400C, SA3400C, SA2400C manufactured by Advanced Softmaterials Inc., and the like.

—Mass of Polyrotaxane Contained in Cured Layer—

The mass of the polyrotaxane contained in the cured layer with respect to the total solid content in the cured layer is preferably 1% to 40% by mass, more preferably 10% to 30% by mass, and even more preferably 15% to 25% by mass. In a case where the mass of polyrotaxane contained in the cured layer is within the above range, both the pencil hardness and the surface roughness can be achieved.

(Inorganic Fine Particles)

In the hardcoat film of the present invention, the cured layer contains inorganic fine particles having an average primary particle diameter of less than 2 μm. In a case where the inorganic fine particles having an average primary particle diameter of less than 2 μm are used, the pencil hardness can be improved. Examples of the inorganic fine particles include silica particles, titanium dioxide particles, zirconium oxide particles, aluminum oxide particles, and the like. Among these, silica particles are preferable.

Generally, the inorganic fine particles exhibit low affinity with respect to an organic component such as a polyfunctional vinyl monomer. Accordingly, in a case where the inorganic fine particles are simply mixed with the cured layer, sometimes an aggregated is formed, or the cured layer having undergone curing easily cracks. Therefore, in the present invention, in order to improve the affinity of the inorganic fine particles with respect to organic components, it is preferable to treat the surface of the inorganic fine particles with a surface modifier having an organic segment.

It is preferable that the surface modifier has a functional group, which can form a bond with the inorganic fine particles or can be adsorbed onto the inorganic fine particles, and a functional group, which has high affinity with an organic component, in the same molecule. As the surface modifier having a functional group which can form a bond with the inorganic fine particles or can be adsorbed onto the inorganic fine particles, a metal alkoxide surface modifier such as silane, aluminum, titanium, and zirconium or a surface modifier having an anionic group such as a phosphoric acid group, a sulfuric acid group, a sulfonic acid group, or a carboxylic acid group is preferable. As the functional group having high affinity with an organic component, functional groups obtained simply by combining an organic component with hydrophilicity and hydrophobicity may be used. However, as the functional group, a functional group that can be chemically bonded to an organic component is preferable, and an ethylenically unsaturated double bond group or a ring-opening polymerizable group is particularly preferable.

In the present invention, the surface modifier for the inorganic fine particles is preferably a curable resin having metal alkoxide or an anionic group and an ethylenically unsaturated double bond group or a ring-opening polymerizable group in the same molecule. By making the functional group chemically bonded to an organic component, crosslinking density of the hardcoat layer is increased, and pencil hardness can be improved.

Typical examples of the aforementioned surface modifiers include a coupling agent containing an unsaturated double bond group, an organic curable resin containing a phosphoric acid group, an organic curable resin containing a sulfuric acid group, and an organic curable resin containing a carboxylic acid group shown below, and the like.

H₂C═C(X)COOC₃H₆Si(OCH₃)₃ S-1

H₂C═C(X)COOC₂H₄OTi(OC₂H₅)₃ S-2

H₂C═C(X)COOC₂H₄OCOC₅H₁₀OPO(OH)₂ S-3

(H₂C═C(X)COOC₂H₄OCOC₅H₁₀O)₂POOH S-4

H₂C═C(X)COOC₂H₄OSO₃H S-5

H₂C═C(X)COO(C₅H₁₀COO)₂H S-6

H₂C═C(X)COOC₅H₁₀COOH S-7

CH₂CH(O)CH₂OC₃H₆Si(OCH₃)₃ S-8

(X represents a hydrogen atom or CH₃)

It is preferable that the surface modification for the inorganic fine particles is performed in a solution. The surface modification may be performed by a method in which a surface modifier is allowed to coexist at the time of mechanically finely dispersing the inorganic fine particles, a method in which the inorganic fine particles are finely dispersed and then a surface modifier is added thereto and stirred, or a method in which the surface modification is performed before the inorganic fine particles are finely dispersed (if necessary, the inorganic fine particles are warmed and dried and then subjected to heating or changing of pH (power of hydrogen)) and then the inorganic fine particles are finely dispersed. As the solution in which the surface modifier is dissolved, an organic solvent having high polarity is preferable, and specific examples thereof include known solvents such as an alcohol, a ketone, and an ester.

Considering the hardness of a coating film, provided that the total solid content of the active energy ray-curable resin composition in the present invention is 100% by mass, the amount of the inorganic fine particles added is preferably 5% to 40% by mass, and more preferably 10% to 30% by mass.

The average primary particle diameter of the inorganic fine particles is less than 2 μm, preferably 10 nm to 1 nm, more preferably 10 nm to 100 μm, and particularly preferably 10 nm to 50 nm. The average primary particle diameter of the inorganic fine particles can be determined from an electron micrograph. From the viewpoint of improving pencil hardness, it is preferable that the average primary particle diameter of the inorganic fine particles is within the aforementioned preferred range. Furthermore, from the viewpoint of inhibiting an increase in haze, it is preferable that the inorganic fine particles have a small average primary particle diameter.

Although the inorganic fine particles may have a spherical shape or a non-spherical shape, it is preferable that each of the inorganic fine particles has a spherical shape. From the viewpoint of imparting hardness, it is more preferable that the inorganic fine particles are present in the cured layer in a non-spherical shape in which two to ten spherical inorganic fine particles are linked to each other. Presumably, by using the inorganic fine particles in which several particles are linearly linked to each other, a strong particle network structure may be formed, and hence the hardness may be improved.

Specific examples of the inorganic fine particles include ELCOM V-8802 (spherical silica particles having an average primary particle diameter of 15 nm manufactured by JGC CORPORATION), ELCOM V-8803 (silica particles of irregular shapes manufactured by JGC CORPORATION), MiBK-SD (spherical silica particles having an average primary particle diameter of 10 to 20 nm manufactured by NISSAN CHEMICAL INDUSTRIES, LTD.), MEK-AC-2140Z (spherical silica particles having an average primary particle diameter of 10 to 20 nm manufactured by NISSAN CHEMICAL INDUSTRIES, LTD.), MEK-AC-4130 (spherical silica particles having an average primary particle diameter of 45 nm manufactured by NISSAN CHEMICAL INDUSTRIES, LTD.), MiBK-SD-L (spherical silica particles having an average primary particle diameter of 40 to 50 nm manufactured by NISSAN CHEMICAL INDUSTRIES, LTD.), MEK-AC-5140Z (spherical silica particles having an average primary particle diameter of 85 nm manufactured by NISSAN CHEMICAL INDUSTRIES, LTD.), and the like. Among these, from the viewpoint of imparting hardness, ELCOM V-8802 is preferable.

(Matt Particles)

In the hardcoat film of the present invention, the cured layer contains matt particles having an average primary particle diameter of equal to or greater than 2 μm, and the mass of the matt particles contained in the cured layer is equal to or greater than 0.10 g/cm³.

In the present invention, the cured layer contains the matt particles having an average primary particle diameter of equal to or greater than 2 μm, such that sufficient surface asperities (preferably a feeling of writing in a case where input is performed using a stylus) are imparted to the cured layer. The average primary particle diameter of the matt particles is preferably 2.0 to 20 μm, more preferably 4.0 to 14 μm, and particularly preferably 6.0 to 10 μm. In a case where the average primary particle diameter is within the above range, appropriate asperities can be imparted to the surface of the cured layer, and a preferred feeling of writing can be obtained.

Specific examples of the matt particles preferably include particles of inorganic compounds such as silica particles and TiO₂ particles, cross-linked acryl particles, cross-linked acryl-styrene particles, cross-linked styrene particles, and resin particles such as melamine resin particles and benzoguanamine resin particles. In the hardcoat film of the present invention, the matt particles are more preferably organic resin particles, and particularly preferably cross-linked acryl particles, cross-linked acryl-styrene particles, or cross-linked styrene particles.

As the matt particles, any of perfectly spherical matt particles and amorphous matt particles can be used. Furthermore, two or more kinds of different matt particles may be used in combination.

The mass of the matt particles contained in the cured layer is equal to or greater than 0.10 g/cm³, preferably 0.10 to 0.40 g/cm³, and more preferably 0.10 to 0.30 g/cm³. In a case where the mass of the matt particles contained in the cured layer is within the above range, the cured layer can express surface asperities (preferably a feeling of writing in a case where input is performed using a stylus).

(Other Materials)

The cured layer or the active energy ray-curable resin composition can also contain a polymerizable compound, a photopolymerization initiator, an antifoulant, a solvent, and the like. If necessary, the active energy ray-curable resin composition can optionally contain one or more kinds of known additives. Examples of such additives include a surface conditioner, a leveling agent, a polymerization inhibitor, and the like. For details of these additives, for example, paragraphs “0032” to “0034” in JP2012-229412A can be referred to. However, the present invention is not limited thereto, and it is possible to use various types of additives that are generally used in photopolymerizable compositions. The amount of the additives added to the active energy ray-curable resin composition may be appropriately adjusted and is not particularly limited.

—Polymerizahle Compound—

As a polymerizable compound, it is preferable to use a radically polymerizable compound or a cationically polymerizable compound.

Regarding the polymerizable compound, a first aspect in which a monomer having two or more ethylenically unsaturated groups is used and a second aspect in which a radically polymerizable compound and a cationically polymerizable compound are used is more preferably used.

First, the first aspect in which a monomer having two or more ethylenically unsaturated groups is used will be described.

Examples of the monomer having two or more ethylenically unsaturated groups include an ester of a polyhydric alcohol and (meth)acrylic acid [for example, ethylene glycol di(meth)acrylate, butanediol di(meth)acrylate, hexanediol di(meth)acrylate, 1,4-cyclohexane diacrylate, pentaerythritol tetra(meth)acrylate, pentaerythritol tri(meth)acrylate, trimethylolpropane tri(meth)acrylate, trimethyolethane tri(meth)acrylate, dipentaerythritol tetra(meth)acrylate, dipentaerythritol penta(meth)acrylate, dipentaerythritol hexa(meth)acrylate, pentaerythritol hexa(meth)acrylate, 1,2,3-cyclohexane tetramethacrylate, polyurethane polyacrylate, or polyester polyacrylate], a monomer obtained by modifying the above ester with ethylene oxide, polyethylene oxide, or caprolactone, vinyl benzene and a derivative thereof [for example, 1,4-divinylbenzene, 4-vinylbenzoic acid-2-acryloyl ethyl ester, or 1,4-divinylcyclohexanone], vinyl sulfone (for example, divinyl sulfone), acrylamide [for example, methylenebisacrylamide], and methacrylamide. Two or more kinds of these monomers may be used in combination.

In a case where the linear molecule of the polyrotaxane is polyalkylene glycols, it is preferable that at least a portion of the monomer having two or more ethylenically unsaturated groups is preferably an ethylene oxide-modified monomer or a polyethylene oxide-modified monomer.

Particularly, in a case where the linear molecule of the polyrotaxane is polyethylene glycol, it is preferable that the polymerizable compound contains an ethylene oxide-modified monomer as at least a portion of the monomer having two or more ethylenically unsaturated groups. In a case where the polymerizable compound contains the ethylene oxide-modified monomer, the compatibility with the polyrotaxane can be improved, and an increase in haze of the cured layer resulting from an insoluble material can be inhibited.

These monomers having ethylenically unsaturated groups can be polymerized by the irradiation of ionizing radiation or heating in the presence of a radical photopolymerization initiator or a radical thermal polymerization initiator.

For example, the cured layer can be formed by preparing a coating solution, which contains polyrotaxane, the aforementioned inorganic fine particles, the aforementioned matt particles, and a monomer for forming a cured resin such as the aforementioned ethylenically unsaturated monomer, a radical photopolymerization initiator, and/or a radical thermal polymerization initiator, coating the base material film with the coating solution, and curing the coating solution through a polymerization reaction by using active energy rays and/or heat.

Next, the second aspect will be described in which a radically polymerizable compound and a cationically polymerizable compound are used.

In this case, it is particularly preferable that the active energy ray-curable resin composition contains a radically polymerizable compound containing two or more radically polymerizable groups selected from the group consisting of an acryloyl group and a methacryloyl group in one molecule; and a cationically polymerizable compound.

Furthermore, in this case, it is preferable that the active energy ray-curable resin composition contains a radical photopolymerization initiator and a cationic photopolymerization initiator. That is, it is preferable that the active energy ray-curable resin composition contains a radically polymerizable compound containing two or more radically polymerizable groups selected from the group consisting of an acryloyl group and a methacryloyl group in one molecule; a cationically polymerizable compound; a radical photopolymerization initiator; and a cationic photopolymerization initiator.

The second aspect is more preferably an aspect 2-1 or an aspect 2-2 that will be described below.

In a preferred aspect of the second aspect, for the active energy ray-curable resin composition, in addition to two or more radically polymerizable groups, polyfunctional (meth)acrylate containing one or more urethane bonds in one molecule is used. The aspect in which the polyfunctional (meth)acrylate containing one or more urethane bonds in one molecule is the aspect 2-1.

In another preferred aspect of the second aspect, for example, in a case where the film thickness of the cured layer is greater than 20 μm, the cured layer contains at least a structure derived from a) component described below, a structure derived from b) component described below, c) component described below, and d) component described below Provided that the total solid content of the cured layer is 100% by mass, in the cured layer, the content of the structure derived from a) component described below is 15% to 70% by mass, the content of the structure derived from b) component described below is 25% to 80% by mass, the content of c) component described below is 0.1% to 10% by mass, and the content of d) component described below is 0.1% to 10% by mass.

a) Compound which contains one alicyclic epoxy group and one ethylenically unsaturated double bond group in a molecule and has a molecular weight of equal to or smaller than 300;

b) Compound which contains three or more ethylenically unsaturated double bond groups in a molecule;

c) Radical photopolymerization initiator;

d) Cationic photopolymerization initiator.

Furthermore, it is preferable that the cured layer is formed by curing the active energy ray-curable resin composition containing at least a), b), c), and d), and provided that the total solid content of the active energy ray-curable resin composition is 100% by mass, the content of a) in the active energy ray-curable resin composition is preferably 15% to 70% by mass. These aspects are regarded as the aspect 2-2.

Hereinafter, each of the polymerizable compounds preferably used in the second aspect will be sequentially described.

—Radically Polymerizable Compound—

It is preferable that the active energy ray-curable resin composition contains at least polyfunctional (meth)acrylate containing two or more radically polymerizable groups selected from the aforementioned group in one molecule, as a radically polymerizable compound. As the polyfunctional (meth)acrylate, only one kind of polyfunctional (meth)acrylate may be used, or two or more kinds of polyfunctional (meth)acrylates having different structures may be used in combination. Furthermore, as a radically polymerizable compound, one or more kinds of polyfunctional (meth)acrylates and one or more kinds of radically polymerizable compounds other than polyfunctional (meth)acrylates may be used in combination. Other radically polymerizable compounds that can be used in combination will be described later. Regarding each of various types of components such as the cationically polymerizable compound, the radical photopolymerization initiator, and the cationic photopolymerization initiator which will be described later, as described above, only one kind of component may be used, or two or more kinds of components having different structures may be used in combination. In addition, in a case where two or more kinds of components having different structures are used in combination, the mass of each of the components contained in the composition refers to the total mass of the component contained in the composition.

At least one kind of radically polymerizable compound (polyfunctional (meth)acrylate) contained in the active energy ray-curable resin composition is specifically a compound containing two or more radically polymerizable groups selected from the group consisting of an acryloyl group and a methacryloyl group in one molecule. The radically polymerizable group (polymerizable group which can be polymerized by a radical) selected from the aforementioned group is a polymerizable group which can be polymerized by light (photopolymerizable group). For forming a cured layer having high hardness, it is useful to use polyfunctional (meth)acrylate containing two or more radically polymerizable groups described above in one molecule as a radically polymerizable compound. Two or more radically polymerizable groups described above contained in the polyfunctional (meth)acrylate may be the same as each other or different from each other as two or more kinds of radically polymerizable groups. The number of radically polymerizable groups selected from the aforementioned group contained in one molecule of the polyfunctional (meth)acrylate is at least 2, which is 2 to 10 for example and preferably 2 to 6. Among the radically polymerizable groups selected from the aforementioned group, an acryloyl group and a methacryloyl group are preferable.

As the polyfunctional (meth)acrylate, a radically polymerizable compound having a molecular weight of equal to or greater than 200 and less than 1,000 is preferable. In the present invention, for a multimer, a molecular weight refers to a weight-average molecular weight which is measured by gel permeation chromatography (GPC) and expressed in terms of polystyrene. As an example of specific measurement conditions for the weight-average molecular weight, the following measurement conditions can be exemplified.

GPC device: HLC-8120 (manufactured by Tosoh Corporation)

Column: TSK gelMultipore HXL-M (manufactured by Tosoh Corporation, 7.8 mm ID (inside diameter)×30.0 cm)

Fluent: tetrahydrofuran (THF)

In the aspect 2-1 which is a preferred aspect of the second aspect, the polyfunctional (meth)acrylate can contain one or more urethane bonds in one molecule in addition to two or more radically polymerizable groups selected from the aforementioned group. Hereinafter, the polyfunctional (meth)acrylate containing one or more urethane bonds in one molecule will be described as “urethane (meth)acrylate” or “first radically polymerizable compound” as well. The aspect in which “urethane (meth)acrylate” or “first radically polymerizable compound” is used is the aspect 2-1.

In the aspect 2-1, the number of urethane bonds contained in one molecule of the first radically polymerizable compound is preferably equal to or greater than 1. From the viewpoint of further improving the hardness of the cured layer to be formed, the number of urethane bonds is 2 or equal to or greater than 2 which is more preferably 2 to 5, for example. In the first radically polymerizable compound containing two or more urethane bonds in one molecule, the radically polymerizable groups selected from the aforementioned group may be bonded to only one of the urethane bonds directly or through a linking group or may be bonded to the two urethane bonds directly or through a linking group. In an aspect, it is preferable that one or more radically polymerizable groups selected from the aforementioned group are bonded to each of the two urethane bonds bonded to each other through a linking group.

More specifically, in the first radically polymerizable compound, the urethane bonds may be directly bonded to the radically polymerizable groups selected, from the aforementioned group, or a linking group may exist between the urethane bonds and the radically polymerizable groups. The linking group is not particularly limited, and examples thereof include a linear or branched saturated or unsaturated hydrocarbon group, a cyclic group, a group obtained by combining two or more hydrocarbon groups or cyclic groups described above, and the like. The number of carbon atoms in the hydrocarbon group is about 2 to 20 for example, but is not particularly limited. Examples of cyclic structures contained in the cyclic group include an aliphatic ring (cyclohexane ring or the like), an aromatic ring (a benzene ring, a naphthalene ring, or the like), and the like. The aforementioned group may or may not have a substituent. Unless otherwise specified, a group described in the present invention and the present specification may or may not have a substituent. In a case where a certain group has a substituent, examples of the substituent include an alkyl group (for example, an alkyl group having 1 to 6 carbon atoms), a hydroxyl group, an alkoxy group (for example, an alkoxy group having 1 to 6 carbon atoms), a halogen atom (for example, a fluorine atom, a chlorine atom, or a bromine atom), a cyano group, an amino group, a nitro group, an acyl group, a carboxyl group, and the like.

The first radically polymerizable compound (urethane (meth)acrylate) described above can be synthesized by a known method or obtained as a commercially available product.

Examples of the synthesis method of the urethane (meth)acrylate include a method of causing a reaction between an alcohol, a polyol, and/or a hydroxyl group-containing compound such as hydroxyl group-containing (meth)acrylate and an isocyanate or, if necessary, esterifying a urethane compound obtained by the reaction by using (meth)acrylic acid. The (meth)acrylic acid includes acrylic acid and methacrylic acid in meaning.

The urethane (meth)acrylate is not limited to the following compounds. Examples of commercially available products of the urethane (meth)acrylate include UA-306H, UA-306I, UA-306T, UA-510H, UF-8001G; UA-101I, UA-101T, AT-600, AH-600, and AI-600 manufactured by KYOEISHA CHEMICAL Co., LTD., U-4HA, U-6HA, U-6LPA, UA-32P, U-15HA, and UA-1100H manufactured by SHIN-NAKAMURA CHEMICAL CO., LTD., SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B manufactured by NIPPON GOSHEI, UL-503LN manufactured by KYOEISHA CHEMICAL Co., LTD., UNIDIC 17-806, UNIDIC 17-813, UNIDIC V-4030, and UNIDIC V-4000BA manufactured by DIC Corporation, EB-1290K manufactured by Daicel-UCB Company, Ltd., HI-COAP AU-2010 and HI-COAP AU-2020 manufactured by TOKUSHIKI Co., Ltd., and the like.

As specific examples of the urethane (meth)acrylate, example compounds A-1 to A-8 will be shown below, but the present invention is not limited to the following specific examples.

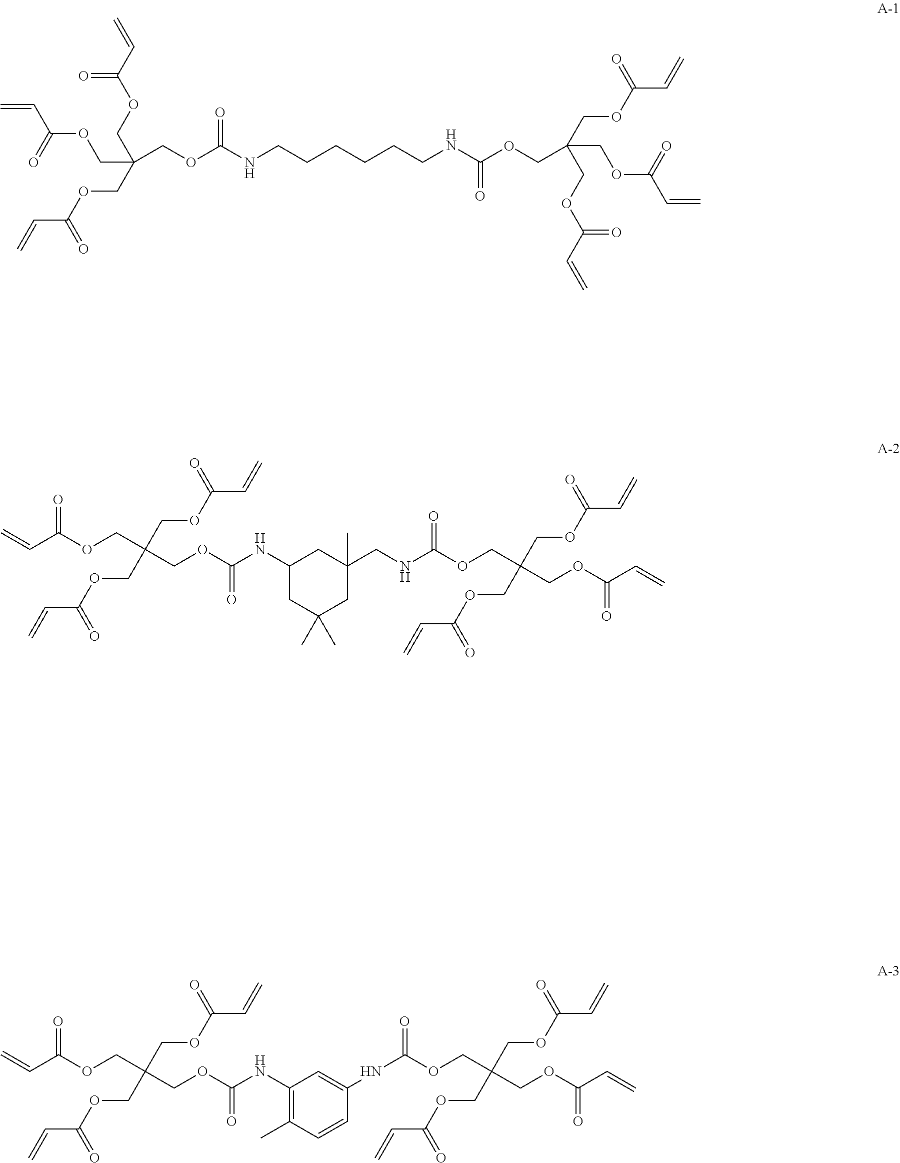

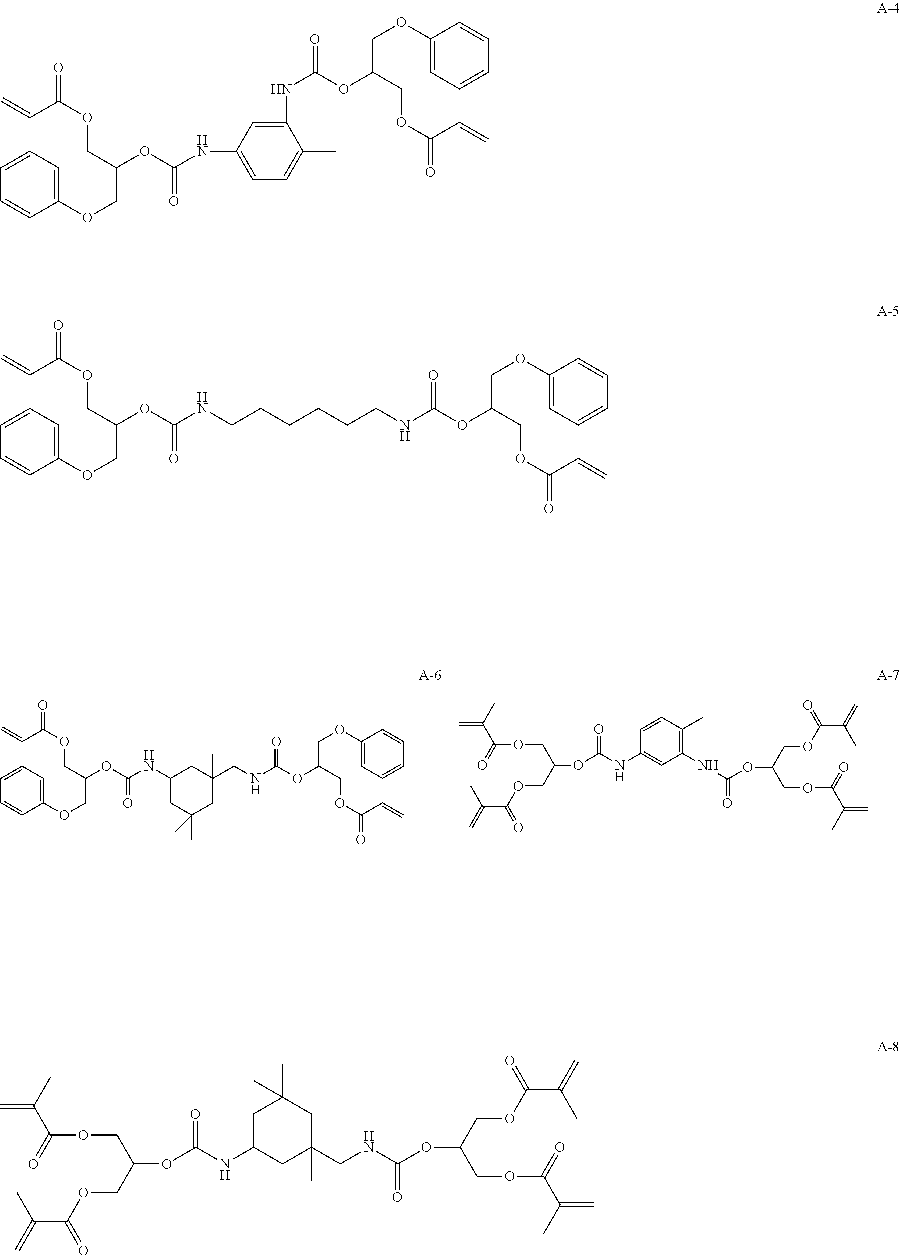 [SMILES: C=CC(=O)OCC(COc1ccccc1)OC(=O)Nc1ccc(C)c(NC(=O)OC(COC(=O)C=C)COc2ccccc2)c1 ; C=CC(=O)OCC(COc1ccccc1)OC(=O)NCCCCCCNC(=O)OC(COC(=O)C=C)COc1ccccc1 ; C=CC(=O)OCC(COc1ccccc1)OC(=O)NCC1(C)CC(NC(=O)OC(COC(=O)C=C)COc2ccccc2)CC(C)(C)C1 ; C=C(C)C(=O)OCC(COC(=O)C(=C)C)OC(=O)Nc1ccc(C)c(NC(=O)OC(COC(=O)C(=C)C)COC(=O)C(=C)C)c1 ; C=C(C)C(=O)OCC(COC(=O)C(=C)C)OC(=O)NCC1(C)CC(NC(=O)OC(COC(=O)C(=C)C)COC(=O)C(=C)C)CC(C)(C)C1]

Hitherto, the urethane (meth)acrylate has been described, but the radically polymerizable compound (preferably polyfunctional (meth)acrylate) containing two or more radically polymerizable groups in one molecule may not have a urethane bond. Furthermore, in the active energy ray-curable resin composition, a compound, which has a radically polymerizable group other than the radically polymerizable group selected from the aforementioned group as a radically polymerizable group, may be used in combination with the aforementioned polyfunctional (meth)acrylate. Hereinafter, a radically polymerizable compound which does not correspond to the first radically polymerizable compound (urethane (meth)acrylate) will be described as “second radically polymerizable compound” as well regardless of whether or not the radically polymerizable compound corresponds to polyfunctional (meth)acrylate. The second radically polymerizable compound which does not correspond to polyfunctional (meth)acrylate may have one or more urethane bonds in one molecule or may not have a urethane bond. From the viewpoint of either or both of the further amelioration of brittleness and the further inhibition of curling, it is preferable to use the first radically polymerizable compound (urethane (meth)acrylate) and the second radically polymerizable compound in combination. From the viewpoint described above, in a case where the active energy ray-curable resin composition contains the first radically polymerizable compound and the second radically polymerizable compound, a mass ratio of first radically polymerizable compound/second radically polymerizable compound is preferably 3/1 to 1/30, more preferably 2/1 to 1/20, and even more preferably 1/1 to 1/10.

The mass of the polyfunctional (meth)acrylate contained in the active energy ray-curable resin composition with respect to a total of 100% by mass of the composition is preferably equal to or greater than 30% by mass, more preferably equal to or greater than 50% by mass, and even more preferably equal to or greater than 70% by mass. Furthermore, the mass of the polyfunctional (meth)acrylate contained in the active energy ray-curable resin composition with respect to a total of 100% by mass of the composition is preferably equal to or smaller than 98% by mass, more preferably equal to or smaller than 95% by mass, and even more preferably equal to or smaller than 90% by mass.

The mass of the first radically polymerizable compound (urethane (meth)acrylate) contained in the active energy ray-curable resin composition with respect to a total of 100% by mass of the composition is preferably equal to or greater than 30% by mass, more preferably equal to or greater than 50% by mass, and even more preferably equal to or greater than 70% by mass. From the viewpoint of further improving the hardness of the cured layer, it is preferable that the composition contains a large amount of first radically polymerizable compound (urethane (meth)acrylate). In contrast, from the viewpoint of further ameliorating brittleness, the mass of the first radically polymerizable compound (urethane (meth)acrylate) contained in the composition with respect to a total of 100% by mass of the composition is preferably equal to or smaller than 98% by mass, more preferably equal to or smaller than 95% by mass, and even more preferably equal to or smaller than 90% by mass.

In an aspect, the second radically polymerizable compound is preferably a compound which contains two or more radically polymerizable groups in one molecule but does not have a urethane bond. The radically polymerizable groups contained in the second radically polymerizable compound are preferably polyfunctional groups having an ethylenically unsaturated double bond. In an aspect, the radically polymerizable groups are preferably vinyl groups. In another aspect, the polyfunctional groups having an ethylenically unsaturated double bond are preferably radically polymerizable groups selected from the aforementioned group. That is, the second radically polymerizable compound is also preferably (meth)acrylate which does not have a urethane bond. In other words, it is also preferable that the second radically polymerizable compound does not have a urethane bond but has radically polymerizable groups selected from the group consisting of an acryloyl group and a methacryloyl group. Furthermore, the second radically polymerizable compound can contain, as radically polymerizable compounds, one or more radically polymerizable group selected from the group consisting of an acryloyl group and a methacryloyl group and one or more other radically polymerizable groups in one molecule.

The number of radically polymerizable groups contained in one molecule of the second radically polymerizable compound is preferably at least 2, more preferably equal to or greater than 3, and even more preferably equal to or greater than 4. In an aspect, the number of radically polymerizable groups contained in one molecule of the second radically polymerizable compound is equal to or smaller than 10 for example, and may be greater than 10. As the second radically polymerizable compound, a radically polymerizable compound having a molecular weight of equal to or greater than 200 and less than 1,000 is preferable.

Examples of the second radically polymerizable compound include the following compounds, but the present invention is not limited to the following example compounds.

Examples of the second radically polymerizable compound include bifunctional (meth)acrylate compounds such as polyethylene glycol 200 di(meth)acrylate, polyethylene glycol 300 di(meth)acrylate, polyethylene glycol 400 di(meth)acrylate, polyethylene glycol 600 di(meth)acrylate, triethylene glycol di(meth)acrylate, epichlorohydrin-modified ethylene glycol di(meth)acrylate (as a commercially available product, for example, DENACOL DA-811 manufactured by NAGASE & CO., LTD. or the like), polypropylene glycol 200 di(meth)acrylate, polypropylene glycol 400 di(meth)acrylate, polypropylene glycol 700 di(meth)acrylate, ethylene oxide (EO) and propylene oxide (PO) block polyether di(meth)acrylate (as a commercially available product, for example, a BLEMMER PET series manufactured by NOF CORPORATION or the like), dipropylene glycol di(meth)acrylate, bisphenol A EO addition-type di(meth)acrylate (as a commercially available product, for example, M-210 manufactured by TOAGOSEI CO., LTD. NK. ESTER A-BPE-20 manufactured by SHIN-NAKAMURA CHEMICAL CO., LTD., or the like), hydrogenated bisphenol A EO addition-type di(meth)acrylate (such as NK ESTER A-HPE-4 manufactured by SHIN-NAKAMURA CHEMICAL CO., LTD.), bisphenol A PO-addition type di(meth)acrylate (as a commercially available product, for example, LIGHT ACRYLATE BP-4PA manufactured by KYOEISHA CHEMICAL Co., LTD., or the like), bisphenol A epichlorohydrin addition-type di(meth)acrylate (as a commercially available product, for example, EBECRYL 150 manufactured by Daicel-UCB Company, Ltd., or the like), bisphenol A EO and PO addition-type di(meth)acrylate (as a commercially available product, for example, BP-023-PE manufactured by TORO Chemical Industry Co., Ltd., or the like), bisphenol F EO addition-type di(meth)acrylate (as a commercially available product, for example, ARONIX M-208 manufactured by TOAGOSEI CO., LTD., or the like), 1,6-hexanediol di(meth)acrylate, 1,6-hexanediol di(meth)acrylate modified with epichlorohydrin, neopentyl glycol di(meth)acrylate, hydroxypivalic acid neopentyl glycol di(meth)acrylate, hydroxypivalic acid neopentyl glycol di(meth)acrylate modified with caprolactone, 1,4-butanediol di(meth)acrylate, 1,9-nonanediol di(meth)acrylate, trimethylolpropane di(meth)acrylate, tricyclodecane dimethanol di(meth)acrylate, pentaerythritol di(meth)acrylate monostearate, trimethylolpropane acrylic acid.benzoic acid ester, and isocyanuric acid EO-modified di(meth)acrylate (as a commercially available product, for example, ARONIX M-215 manufactured by TOAGOSEI CO., LTD., or the like).

Examples of the second radically polymerizable compound also include trifunctional (meth)acrylate compounds such as trimethylolpropane tri(meth)acrylate, trimethylolpropane tri(meth)acrylate modified with EO, PO, or epichlorohydrin, pentaerythritol tri(meth)acrylate, glycerol tri(meth)acrylate, glycerol tri(meth)acrylate modified with EO, PO, or epichlorohydrin, isocyanuric acid EO-modified tri(meth)acrylate (as a commercially available product, for example, ARONIX M-315 manufactured by TOAGOSEI CO., LTD., or the like), tris(meth)acryloyloxyethyl phosphate, (2,2,2-tri-(meth)acryloyloxymethyl)ethyl hydrogen phthalate, glycerol tri(meth)acrylate, and glycerol tri(meth)acrylate modified with EO, PO, or epichlorohydrin; tetrafunctional (meth)acrylate compounds such as pentaerythritol tetra(meth)acrylate, pentaerythritol tetra(meth)acrylate modified with EO, PO, or epichlorohydrin, and ditrimethylolpropane tetra(meth)acrylate; pentafunctional (meth)acrylate compounds such as dipentaerythritol penta(meth)acrylate and dipentaerythritol penta(meth)acrylate modified with EO, PO, epichlorohydrin, fatty acid, or alkyl; and hexafunctional (meth)acrylate compounds such as dipentaerythritol hexa(meth)acrylate, dipentaerythritol hexa(meth)acrylate modified with EO, PO, epichlorohydrin, fatty acid, or alkyl, sorbitol hexa(meth)acrylate, and sorbitol hexa(meth)acrylate modified with EO, PO, epichlorohydrin, fatty acid, or alkyl.

Two or more kinds of second radically polymerizable compounds may be used in combination. In this case, it is possible to preferably use “DPHA” (manufactured by Nippon Kayaku Co., Ltd.) which is a mixture of dipentaerythritol pentaacrylate and dipentaerythritol hexaacrylate, and the like.

As the second radically polymerizable compound, polyester meth)acrylate and epoxy (meth)acrylate having a weight-average molecular weight equal to or greater than 200 and less than 1,000 are also preferable. Examples thereof include commercially available polyester (meth)acrylate products such as a BEAMSET (trade name) 700 series, that is, BEAMSET 700 (hexafunctional), BEAMSET 710 (tetrafunctional), and BEAMSET 720 (trifunctional) manufactured by Arakawa Chemical Industries, Ltd., and the like. Examples of the epoxy (meth)acrylate include an SP series such as SP-1506, 500, SP-1507, and 480 (trade names) as well as a VR series such as VR-77 manufactured by Showa Highpolymer Co., Ltd., EA-1010/ECA, EA-11020, EA-1025, EA-6310/ECA (trade names) manufactured by SHIN-NAKAMURA CHEMICAL CO., LTD., and the like.

Specific examples of the second radically polymerizable compound include the following example compounds A-9 to A-11.

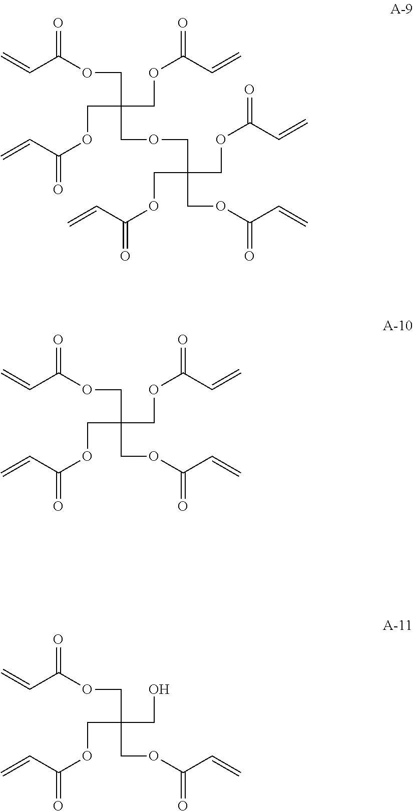

In the aspect 2-2 which is a preferred aspect of the second aspect, b) compound which contains three of more ethylenically unsaturated double bond groups in a molecule is used. b) Compound which has three or more ethylenically unsaturated double bond groups in a molecule will be referred to as “b) component” as well.

Because b) component has three or more ethylenically unsaturated double bond groups in a molecule, high hardness can be exhibited.

Examples of b) component include an ester of a polyhydric alcohol and (meth)acrylic acid, vinyl benzene and a derivative thereof, vinyl sulfone, (meth)acrylamide, and the like. Among these, from the viewpoint of hardness, a compound having three or more (meth)acryloyl groups is preferable, and examples thereof include an acrylate-based compound that is widely used in the field of the related art and forms a cured substance having high hardness. Examples of such a compound include a compound which is an ester of a polyhydric alcohol and (meth)acrylic acid and has three or more ethylenically unsaturated double bond groups in a molecule. Examples thereof include (di)pentaerythritol tetra(meth)acrylate, (di)pentaerythritol tri(meth)acrylate, trimethylolpropane tri(meth)acrylate, EO-modified trimethylolpropane tri(meth)acrylate, PO-modified trimethylolpropane tri(meth)acrylate, EO-modified phosphoric acid tri(meth)acrylate, trimethylolethane tri(meth)acrylate, ditrimethylolpropane tetra(meth)acrylate, dipentaerythritol tetra(meth)acrylate, (di)pentaerythritol penta(meth)acrylate, dipentaerythritol hexa(meth)acrylate, pentaerythritol hexa(meth)acrylate, 1,2,3-cyclohexane tetramethacrylate, polyurethane polyacrylate, polyester polyacrylate, caprolactone-modified tris(acryloxyethyl)isocyanurate, tripentaerythritol triacrylate, tripentaerythritol hexatriacrylate, 1,2,4-cyclohexane tetra(meth)acrylate, pentaglycerol triacrylate, and the like.

As b) component, a resin having three or more (meth)acryloyl groups, polyfunctional (meth)acrylate having three or more (meth)acryloyl groups, and urethane (meth)acrylate are also preferable.

Examples of the resin (an oligomer or a prepolymer) having three or more (meth)acryloyl groups include oligomers and prepolymers such as a polyester resin, a polyether resin, an acrylic resin, an epoxy resin, a urethane resin, an alkyd resin, a spiroacetal resin, a polybutadiene resin, a polythiol polyene resin, and a polyfunctional compound including a polyhydric alcohol.

Specific examples of the polyfunctional (meth)acrylate having three or more (meth)acryloyl groups include example compounds shown in paragraph “0096” in JP2007-256844A.

Specific examples of polyfunctional acrylate-based compounds having three or more (meth)acryloyl groups include KAYARAD DPHA, KAYARAD DPHA-2C, KAYARAD PET-30, KAYARAD TMPTA, KAYARAD TPA-320, KAYARAD TPA-330, KAYARAD RP-1040, KAYARAD T-1420, KAYARAD D-310, KAYARAD DPCA-20, KAYARAD DPCA-30, KAYARAD DPCA-60, and KAYARAD GPO-303 manufactured by Nippon Kayaku Co., Ltd., and a compound obtained by esterifying a polyol and (meth)acrylic acid, such as V#400 and V#36095D manufactured by OSAKA ORGANIC CHEMICAL INDUSTRY LTD. Furthermore, it is possible to suitably use urethane acrylate compounds having three or more functional groups, such as SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B (manufactured by NIPPON GOHSEI), UL-503LN (manufactured by KYOEISHA CHEMICAL Co., LTD), UNIDIC 17-806, UNIDIC 17-813, UNIDIC V-4030, and UNIDIC V-4000BA (manufactured by DIC Corporation), EB-1290K, EB-220, EB-5129, EB-1830, and EB-4358 (manufactured by Daicel-UCB Company, Ltd.), HI-COAP AU-2010 and HI-COAP AU-2020 (manufactured by TOKUSHIKI Co., Ltd.), ARONIX M-1960 (manufactured by TOAGOSEI CO., LTD.), ART RESIN UN-3320HA, UN-3320HC, UN-3320HS, UN-904, and HDP-4T, polyester compounds having three or more functional groups such as ARONIX M-8100, M-8030, and M-9050 (manufactured by TOAGOSEI CO., LTD.) and KBM-8307 (manufactured by Daicel SciTech), and the like.

b) Component may be constituted with a single compound, or a plurality of compounds may be used in combination as b) component.

Provided that the total solid content of the cured layer is 100% by mass, the content of the structure derived from b) component in the cured layer is 25% to 80% by mass. Provided that the total solid content of the active energy ray-curable resin composition is 100% by mass, the content of b) component in the composition is 25% to 80% by mass. In a case where the mass of the structure derived from b) component or the mass of b) component contained in the cured layer or the active energy ray-curable resin composition is equal to or greater than 20% by mass, it is possible to obtain sufficient hardness. In contrast, in a case where the mass of the structure derived from b) component or the mass of b) component contained in the cured layer or the active energy ray-curable resin composition is equal to or smaller than 80% by mass, the mass of the structure derived from a) component or the mass of a) component contained in the cured layer or the composition is reduced, and accordingly, the smoothness of the cured layer becomes sufficient.

Provided that the total solid content of the cured layer is 100% by mass, the content of the structure derived from b) component in the cured layer is preferably 40% to 75% by mass, and more preferably 60% to 75% by mass. Provided that the total solid content of the active energy ray-curable resin composition is 100% by mass, the content of a) component in the composition is preferably 40% to 75% by mass, and more preferably 60% to 75% by mass.

—Cationically Polymerizable Compound—

It is preferable that the active energy ray-curable resin composition contains a cationically polymerizable compound together with the aforementioned radically polymerizable compound. As described above, according to the inventors of the present inventions, presumably, in a case where the composition contains a cationically polymerizable compound, the cationically polymerizable compound may contribute to the inhibition of the occurrence of curling in the formed cured layer and to the amelioration of brittleness.

Any cationically polymerizable compound can be used without limitation as long as the cationically polymerizable compound has a polymerizable group which can be cationcally polymerized (cationically polymerizable group). The number of cationically polymerizable groups contained in one molecule is at least 1. The cationically polymerizable compound may be a monofunctional compound containing one cationically polymerizable group or a polyfunctional compound containing two or more cationically polymerizable groups. The number of cationically polymerizable groups contained in the polyfunctional compound is not particularly limited, and 2 to 6 for example. Two or more cationically polymerizable groups contained in the polyfunctional compound may be the same as each other or different from each other as two or more kinds of cationically polymerizable groups.

In an aspect, it is preferable that the cationically polymerizable compound has one or more radically polymerizable groups together with a cationically polymerizable group. Regarding the radically polymerizable groups contained in the cationically polymerizable compound, the above description relating to the radically polymerizable compound can be referred to. The radically polymerizable groups are preferably polyfunctional groups having an ethylenically unsaturated double bond, and the polyfunctional groups having an ethylenically unsaturated double bond are more preferably a vinyl group and a radically polymerizable group selected from the aforementioned group. The number of radically polymerizable groups in one molecule of the cationically polymerizable compound having radically polymerizable groups is at least 1, preferably 1 to 3, and more preferably 1.

Examples of the cationically polymerizable group preferably include an oxygen-containing heterocyclic group and a vinyl ether group. The cationically polymerizable compound may contain one or more oxygen-containing heterocyclic groups and one or more vinyl ether groups in one molecule.

The oxygen-containing heterocyclic ring may be a monocyclic ring or a fused ring. Furthermore, it is also preferable that the oxygen-containing heterocyclic ring has a bicyclo skeleton. The oxygen-containing heterocyclic ring may be a non-aromatic ring or an aromatic ring, and is preferably a non-aromatic ring. Specific examples of the monocyclic ring include an epoxy ring, a tetrahydrofuran ring, and an oxetane ring. Examples of the oxygen-containing heterocyclic ring having a bicyclo skeleton include an oxabicyclo ring. The cationically polymerizable group containing the oxygen-containing heterocyclic ring is contained in the cationically polymerizable compound as a monovalent substituent or a polyvalent substituent with a valency of 2 or higher. The aforementioned fused ring may be a ring formed by the fusion of two or more oxygen-containing heterocyclic rings or a ring formed by the fusion of one or more oxygen-containing heterocyclic rings and one or more ring structures other than the oxygen-containing heterocyclic ring. The ring structure other than the oxygen-containing heterocyclic ring is not limited to the above, and examples thereof include a cycloalkane ring such as a cyclohexane ring.

Specific examples of the oxygen-containing heterocyclic ring will be shown below, but the present invention is not limited to the specific examples.

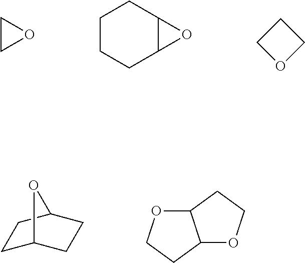

The cationically polymerizable compound may have a partial structure other than the cationically polymerizable group. The partial structure is not particularly limited, and may be a linear, branched, or cyclic structure. The partial structure may contain one or more heteroatoms such as oxygen atoms or nitrogen atoms.

As a preferred aspect of the cationically polymerizable compound, a compound (cyclic structure-containing compound) can be exemplified which has a cyclic structure as the cationically polymerizable group or as a partial structure other than the cationically polymerizable group. The cyclic structure-containing compound may have one cyclic structure, for example, and the cyclic structure-containing compound may have two or more cyclic structures. The number of cyclic structures contained in the cyclic structure-containing compound is 1 to 5 for example, but is not particularly limited. In a case where the compound contains two or more cyclic structures, the cyclic structures may be the same as each other. Alternatively, the compound may contain two or more kinds of cyclic structures having different structures.

As an example of the cyclic structure contained in the cyclic structure-containing compound, an oxygen-containing heterocyclic ring can be exemplified. The details of the oxygen-containing heterocyclic ring are as described above.

By dividing the molecular weight of the cationically polymerizable compound (hereinafter, described as “B”) by the number of cationically polymerizable groups (hereinafter, described as “C”) contained in one molecule of the cationically polymerizable compound, a cationically polymerizable group equivalent (=B/C) is obtained. The cationically polymerizable group equivalent is equal to or smaller than 300 for example, and from the viewpoint of forming a cured layer exhibiting excellent adhesiveness with respect to the base material film in the hardcoat film, the cationically polymerizable group equivalent is preferably less than 150. In contrast, from the viewpoint of hygroscopicity of the cured layer, the cationically polymerizable group equivalent is preferably equal to or greater than 50. In an aspect, the cationically polymerizable group contained in the cationically polymerizable compound that results in the cationically polymerizable group equivalent within the above range can be an epoxy group (epoxy ring). That is, in an aspect, the cationically polymerizable compound is an epoxy ring-containing compound. From the viewpoint of forming a cured layer exhibiting excellent adhesiveness with respect to the base material film in the hardcoat film, in the epoxy ring-containing compound, an epoxy group equivalent, which is obtained by dividing the molecular weight of the compound by the number of epoxy rings contained in one molecule, is preferably less than 150. Furthermore, the epoxy group equivalent of the epoxy ring-containing compound is equal to or greater than 50, for example.

The molecular weight of the cationically polymerizable compound is preferably equal to or smaller than 500, and more preferably equal to or smaller than 300. Presumably, in a case where the molecular weight is within the above range, the cationically polymerizable compound may easily permeate the base material film, and hence a cured layer having excellent adhesiveness could be formed.

In the aspect 2-2, a) compound which contains one alicyclic epoxy group and one ethylenically unsaturated double bond group in a molecule and has a molecular weight of equal to or smaller than 300 is used.

a) Compound which contains one alicyclic epoxy group and one ethylenically unsaturated double bond group in a molecule and has a molecular weight of equal to or smaller than 300 will be described. a) Compound which contains one alicyclic epoxy group and one ethylenically unsaturated double bond group in a molecule and has a molecular weight of equal to or smaller than 300 will be referred to as “a) component” as well.

Examples of the ethylenically unsaturated double bond group include a (meth)acryloyl group, a vinyl group, a styryl group, an allyl group, and the like. Among these, a (meth)acryloyl group and —C(O)OCH═CH₂ are preferable, and a (meth)acryloyl group is particularly preferable. By having the ethylenically unsaturated double bond group, the compound can maintain high hardness, and moisture-heat resistance can be imparted.

The number of each of the epoxy groups and each of the ethylenically unsaturated double bond groups in a molecule is preferably 1, because in a case where the number of each of the functional groups is 1, the number of functional groups (the epoxy group and the ethylenically unsaturated double bond group) becomes smaller than in a case where the number of each of the functional groups is 2, and accordingly, the molecular weight is reduced, and pencil hardness is improved.

The molecular weight of a) component is equal to or smaller than 300, preferably equal to or smaller than 210, and more preferably equal to or smaller than 200.

In a case where the molecular weight is equal to or smaller than 300, the number of moieties other than the epoxy group and the ethylenically unsaturated double bond group is reduced, and hence pencil hardness can be improved.

From the viewpoint of inhibiting volatilization at the time of forming the cured layer, the molecular weight of a) component is preferably equal to or greater than 100 and more preferably equal to or greater than 150.

a) Component is not limited as long as it contains one alicyclic epoxy group and one ethylenically unsaturated double bond group in a molecule and has a molecular weight of equal to or smaller than 300. As a) component, a compound represented by General Formula (1) is preferable.

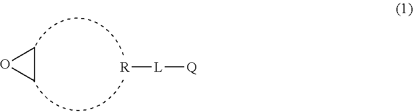

In General Formula (1), R represents monocyclic hydrocarbon or cross-linked hydrocarbon, L represents a single bond or a divalent linking group, and Q represents an ethylenically unsaturated double bond group.

In a case where R in General Formula (1) is monocyclic hydrocarbon, the monocyclic hydrocarbon is preferably alicyclic hydrocarbons. Among these, an alicyclic group having 4 to 10 carbon atoms is more preferable, an alicyclic group having 5 to 7 carbon atoms is even more preferable, and an alicyclic group having 6 carbon atoms is particularly preferable. Specifically, a cyclobutyl group, a cyclopentyl group, a cyclohexyl group, and a cycloheptyl group are preferable, and a cyclohexyl group is particularly preferable.

In a case where R in General Formula (1) is cross-linked hydrocarbon, a bicyclic crosslink (bicycle ring) and a tricyclic crosslink (tricyclo ring) are preferable. In a case where R in General Formula (1) represents cross-linked hydrocarbon, cross-linked hydrocarbon having 5 to 20 carbon atoms is more preferable. Specifically, a norbornyl group, a bornyl group, an isobornyl group, a tricyclodecyl group, a dicyclopentenyl group, dicyclopentenyl group, a tricyclopentenyl group, a tricyclopentanyl group, an adamantyl group, an adamantyl group substituted with a lower alkyl group, and the like are even more preferable.

In a case where L represents a divalent linking group, a divalent aliphatic hydrocarbon group is preferable. The number of carbon atoms in the divalent aliphatic hydrocarbon group is preferably 1 to 6, more preferably 1 to 3, and even more preferably 1. The divalent aliphatic hydrocarbon group is preferably a linear, branched, or cyclic alkylene group, more preferably a linear or branched alkylene group, and even more preferably a linear alkylene group.

Examples of Q include polymerizable functional groups such as a (meth)acryloyl group, a vinyl group, a styryl group, and an allyl group. Among these, a (meth)acryloyl group and —C(O)OCH═₂ are preferable, and a (meth)acryloyl group is particularly preferable.

The specific compound as a) component is not particularly limited as long as it is a compound which contains one alicyclic epoxy group and one ethylenically unsaturated double bond group in a molecule and has a molecular weight equal to or smaller than 300. As the compound, it is possible to use the compound described in paragraph “0015” in JP1998-17614A (JP-H10-17614A), a compound represented by General Formula (1A) or 1B), 1,2-epoxy-4-vinylcyclohexane, and the like.

Among these, the compound represented by General Formula (1A) or (1B) is more preferable, and the compound represented by General Formula (1A) having a low molecular weight is even more preferable. An isomer of the compound represented by General Formula (1A) is also preferable. In General Formula (1A), L₂ represents a divalent aliphatic hydrocarbon group having 1 to 6 carbon atoms. The number of carbon atoms in L₂ is more preferably 1 to 3. From the viewpoint of improving smoothness of the cured layer, the number of carbon atoms in L₂ is even more preferably 1 (that is, a) component is even more preferably epoxycyclohexyl methyl (meth)acrylate).

By using these compounds, it is possible to simultaneously achieve both of the high pencil hardness and the excellent smoothness at a higher level.

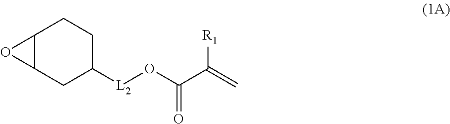

In General Formula (1A), R₁ represents a hydrogen atom or a methyl group, and L₂ represents a divalent aliphatic hydrocarbon group having 1 to 6 carbon atoms.

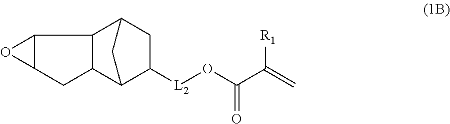

In General Formula (1B), R₁ represents a hydrogen atom or a methyl group, and L₂ represents a divalent aliphatic hydrocarbon group having 1 to 3 carbon atoms.

The number of carbon atoms in the divalent aliphatic hydrocarbon group represented by L² in General Formulae (1A) and (1B) is 1 to 6, more preferably 1 to 3, and even more preferably 1. The divalent aliphatic hydrocarbon group is preferably a linear, branched, or cyclic alkylene group, more preferably a linear or branched alkylene group, and even more preferably a linear alkylene group.

Provided that the total solid content of the cured layer is 100% by mass, the content of the structure derived from a) component in the cured layer is 15% by mass to 70% by mass. Provided that the total solid content of the active energy ray-curable resin composition is 100% by mass, the content of a) component in the composition is 15% to 70% by mass. In a case where the mass of the structure derived from a) component or a) component contained in the cured layer or the active energy ray-curable resin composition is equal to or greater than 15% by mass, an effect of improving the surface smoothness of the cured layer is sufficiently obtained. In contrast, in a case where the mass of the structure derived from a) component or a) component contained in the cured layer or the active energy ray-curable resin composition is equal to or smaller than 70% by mass, the surface hardness can be sufficiently improved.

Provided that the total solid content of the cured layer is 100% by mass, the content of the structure derived from a) component in the cured layer is preferably 18% to 50% by mass, and more preferably 22% to 40% by mass. Provided that the total solid content of the active energy ray-curable resin composition is 100% by mass, the content of a) component in the composition is preferably 18% to 50% by mass, and more preferably 22% to 40% by mass.

As another example of the cyclic structure contained in the cyclic structure-containing compound, a nitrogen-containing heterocyclic ring can be exemplified. The compound containing a nitrogen-containing heterocyclic ring is a cationically polymerizable compound which is preferred from the viewpoint of forming a cured layer exhibiting excellent adhesiveness with respect to the base material film in the hardcoat film. As the compound containing a nitrogen-containing heterocyclic ring, a compound is preferable which has one or more nitrogen-containing heterocyclic rings selected from the group consisting of an isocyanurate ring (nitrogen-containing heterocyclic ring contained in example compounds B-1 to B-3 which will be described later) and a glycoluril ring (nitrogen-containing heterocyclic ring contained in an example compound B-10 which will be described later) in one molecule. Among these, from the viewpoint of forming a cured layer exhibiting excellent adhesiveness with respect to the base material film in the hardcoat film, the compound containing an isocyanurate ring (isocyanurate ring-containing compound) is preferred as a cationically polymerizable compound, because, according to the inventors of the present invention, the isocyanurate ring is assumed to have excellent affinity with the resin constituting the base material film. In this respect, a base material film containing an acrylic resin film is more preferable, and it is even more preferable that the surface directly in contact with the cured layer is the surface of the acrylic resin film.

As another example of the cyclic structure contained in the cyclic structure-containing compound, an alicyclic ring structure can be exemplified. Examples of the alicyclic ring structure include a cyclo ring, a dicyclo ring, and a tricyclo ring. Specific examples thereof include a dicyclopentanyl ring, a cyclohexane ring, and the like.

The cationically polymerizable compound described so far can be synthesized by a known method, and can be obtained as a commercially available product.

Specific examples of the cationically polymerizable compound containing an oxygen-containing heterocyclic ring as a cationically polymerizable group include 3,4-epoxycyclohexylmethyl methacrylate (commercially available products such as CYCLOMER M-100 manufactured by DAICEL CORPORATION), 3,4-epoxycyclohexylmethyl-3′,4′-epoxycyclohexane carboxylate (for example, commercially available products such as UVR 6105 and UVR 6110 manufactured by Union Carbide Corporation and CELLOXIDE 2021 manufactured by Daicel Corporation), bis(3,4-epoxycyclohexylmethyl)adipate (such as UVR 6128 manufactured by Union Carbide Corporation), vinylcyclohexene monoepoxide (such as CELLOXIDE 2000 manufactured by DAICEL CORPORATION), ε-caprolactam-modified 3,4-epoxycyclohexylmethyl 3′,4′-epoxycyclohexane carboxylate (such as CELLOXIDE 2081 manufactured by DAICEL CORPORATION), 1-methyl-4-(2-methyloxiranyl)-7-oxabicyclo[4,1,0]heptane (such as CELLOXIDE 3000 manufactured by DAICEL CORPORATION), 7,7′-dioxa-3,3′-bi[bicyclo[4.1.0]heptane] (such as CELLOXIDE 8000 manufactured by DAICEL CORPORATION), 3-ethyl-3-hydroxymethyloxetane, 1,4bis{[(3-ethyl-3-oxetanyl)methoxy]methyl}benzene, 3-ethyl-3-(phenoxymethyl)oxetane, 3-ethyl-3-(2-ethylhexyloxymethyl)oxetane, di[1-ethyl(3-oxetanyl)]methyl ether, and the like.

Specific examples of the cationically polymerizable compound containing a vinyl ether group as a cationically polymerizable group include 1,4-butanediol divinyl ether, 1,6-hexanediol divinyl ether, nonanediol divinyl ether, cyclohexanediol divinyl ether, cyclohexane dimethanol divinyl ether, triethylene glycol divinyl ether, trimethylolpropane trivinyl ether, pentaerythritol tetravinyl ether, and the like. As the cationically polymerizable compound containing a vinyl ether group, those having an alicyclic structure are also preferable.

Furthermore, as the cationically polymerizable compound, it is possible to use the compounds exemplified in JP1996-143806A (JP-H08-143806A), JP1996-283320A (JP-H08-283320A), JP2000-186079A, JP2000-327672A, JP2004-315778A, JP2005-29632A, and the like.

As specific examples of the cationically polymerizable compound, example compounds B-1 to B-14 will be shown below, but the present invention is not limited to the following specific examples.

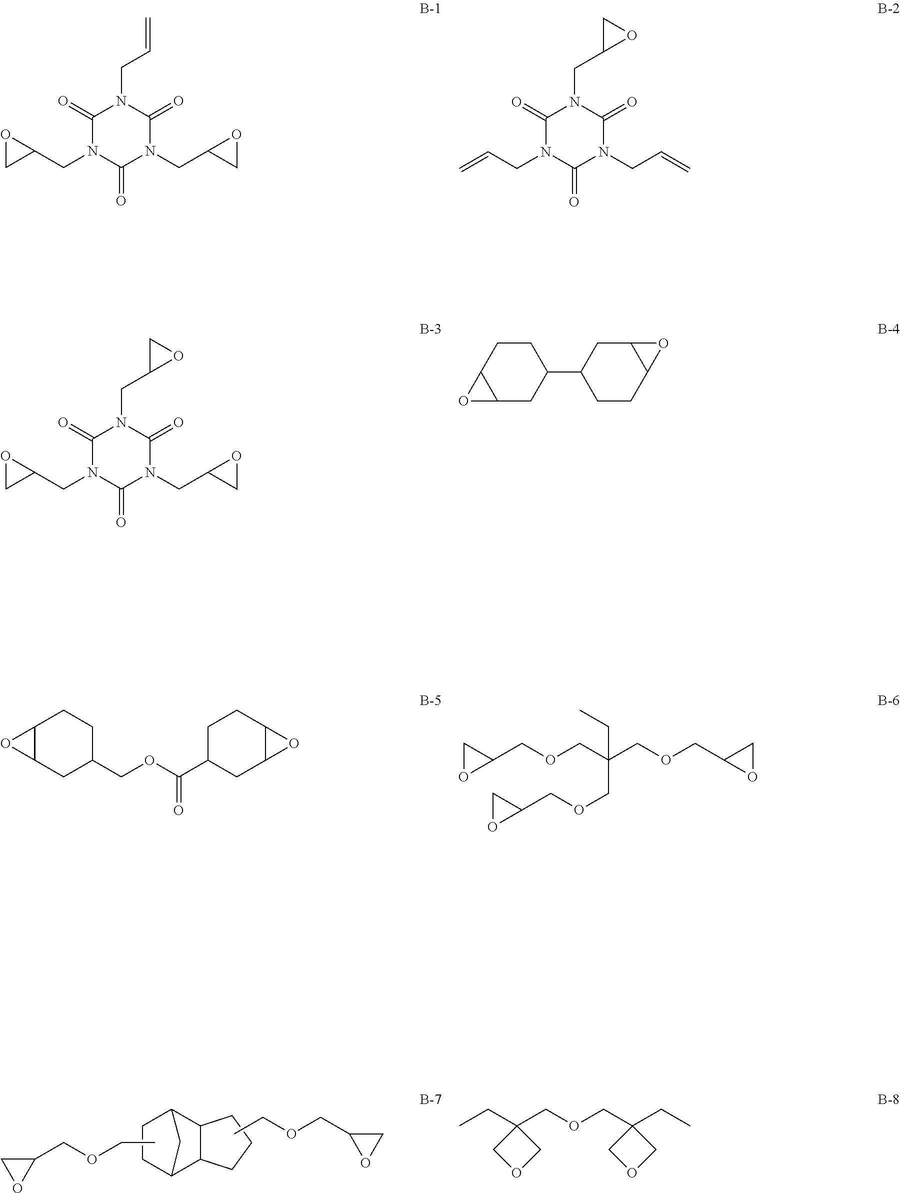

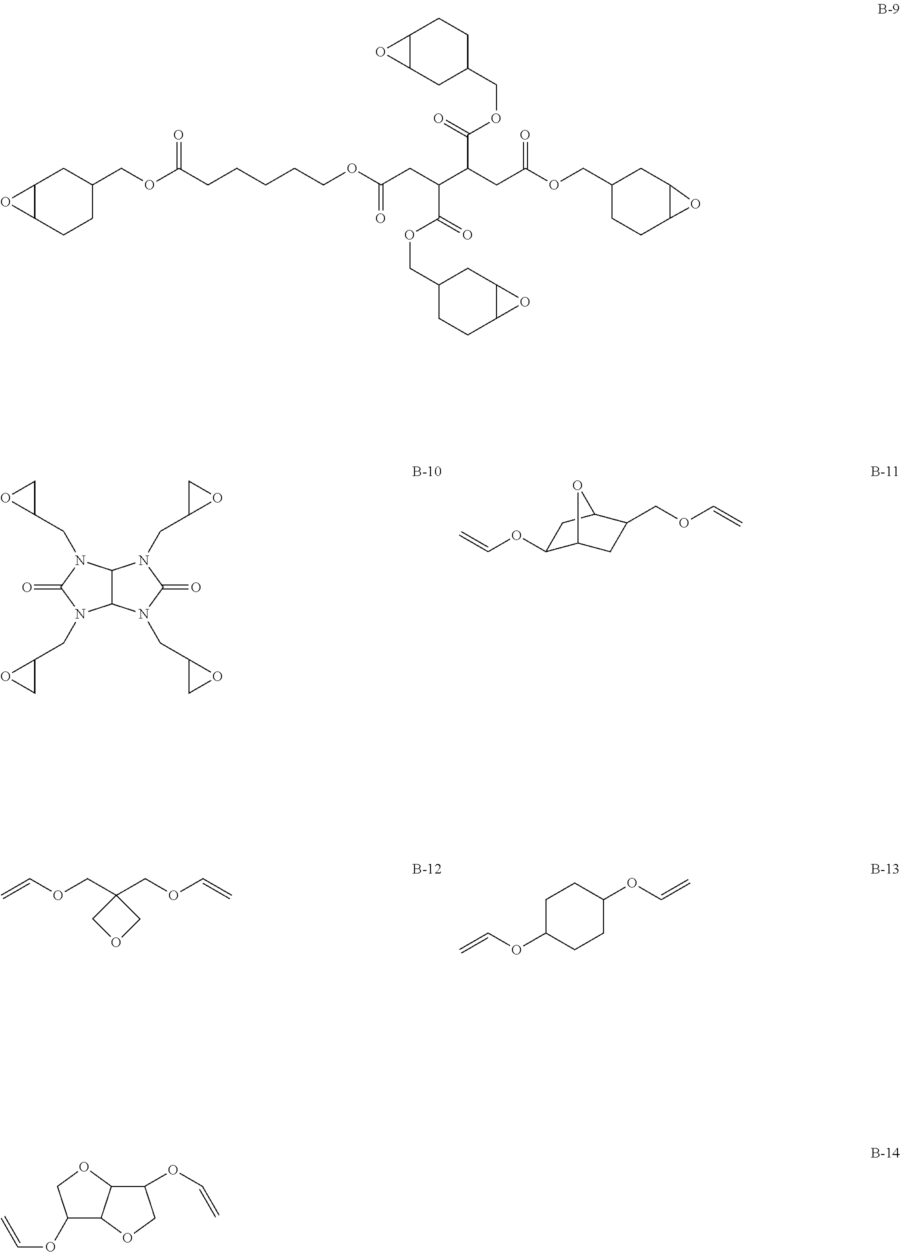 [SMILES: O=C(CCCCCOC(=O)CC(C(=O)OCC1CCC2OC2C1)C(CC(=O)OCC1CCC2OC2C1)C(=O)OCC1CCC2OC2C1)OCC1CCC2OC2C1 ; O=C1N(CC2CO2)C2C(N1CC1CO1)N(CC1CO1)C(=O)N2CC1CO1 ; C=COCC1CC2OC1CC2OC=C ; C=COCC1(COC=C)COC1 ; C=COC1CCC(OC=C)CC1 ; C=COC1COC2C(OC=C)COC12]

From the viewpoint of forming a cured layer exhibiting excellent adhesiveness with respect to the base material film in the hardcoat film, the following aspects can be exemplified as preferred aspects of the aforementioned active energy ray-curable resin composition relating to the cationically polymerizable compound. The composition more preferably satisfies one or more aspects among the following aspects, even more preferably satisfies two or more aspects, still more preferably satisfies three or more aspects, and yet more preferably satisfies all of the aspects. Herein, it is also preferable that one cationically polymerizable compound satisfies a plurality of aspects. For example, in a preferred aspect, the compound containing a nitrogen-containing heterocyclic ring has a cationically polymerizable group equivalent of less than 150.

(1) The active energy ray-curable resin composition contains a compound containing a nitrogen-containing heterocyclic ring as a cationically polymerizable compound. It is preferable that the nitrogen-containing ring contained in the compound containing a nitrogen-containing heterocyclic ring is selected from the group consisting of an isocyanurate ring and a glycoluril ring. The compound containing a nitrogen-containing heterocyclic ring is more preferably an isocyanurate ring-containing compound. It is more preferable that the isocyanurate ring-containing compound is an epoxy ring-containing compound containing one or more epoxy rings in one molecule.

(2) The active energy ray-curable resin composition contains a cationically polymerizable compound having a cationically polymerizable group equivalent of less than 150 as a cationically polymerizable compound. It is preferable that the composition contains an epoxy group-containing compound having an epoxy group equivalent of less than 150.

(3) The active energy ray-curable resin composition contains a functional group having an ethylenically unsaturated double bond as a cationically polymerizable compound.

(4) The active energy ray-curable resin composition contains an oxetane ring-containing compound containing one or more oxetane rings in one molecule as a cationically polymerizable compound, together with other cationically polymerizable compounds. It is preferable that the oxetane ring-containing compound is a compound which does not contain a nitrogen-containing heterocyclic ring.

The mass of the cationically polymerizable compound contained in the active energy ray-curable resin composition with respect to a total of 100 parts by mass of the polyfunctional (meth)acrylate and the cationically polymerizable compound contained in the composition is preferably equal to or greater than 10 parts by mass, more preferably equal to or greater than 15 parts by mass, and even more preferably equal to or greater than 20 parts by mass. Furthermore, the mass of the cationically polymerizable compound contained in the active energy ray-curable resin composition with respect to a total of 100 parts by mass of the first radically polymerizable compound and the cationically polymerizable compound contained in the composition is preferably equal to or greater than 0.05 parts by mass, more preferably equal to or greater than 0.1 parts by mass, and even more preferably equal to or greater than 1 part by mass. From the viewpoint of further inhibiting the occurrence of curling in the cured layer and to further ameliorating brittleness, it is preferable that the composition contains a large amount of cationically polymerizable compound. In contrast, from the viewpoint of further improving the hardness of the cured layer, it is preferable that the proportion of the first radically polymerizable compound in the polymerizable compounds contained in the active energy ray-curable resin composition is high. In this respect, the mass of the cationically polymerizable compound contained in the composition with respect to a total of 100 parts by mass of the first radically polymerizable compound and the cationically polymerizable compound contained in the composition is preferably equal to or smaller than 50 parts by mass, and more preferably equal to or smaller than 40 parts by mass. Furthermore, the mass of the cationically polymerizable compound contained in the composition with respect to a total of 100 parts by mass of the polyfunctional (meth)acrylate and the cationically polymerizable compound contained in the composition is preferably equal to or smaller than 50 parts by mass.

In the present invention, a compound having both the cationically polymerizable group and the radically polymerizable group is classified as a cationically polymerizable compound so as to specify the mass thereof contained in the active energy ray-curable resin composition.

—Photopolymerization Initiator—

The active energy ray-curable resin composition preferably contains a photopolymerization initiator, and more preferably contains a radical photopolymerization initiator and a cationic photopolymerization initiator. Only one kind of radical photopolymerization initiator may be used, or two or more kinds thereof having different structures may be used in combination. The same will be applied to the cationic photopolymerization initiator.

Hereinafter, each of the photopolymerization initiators will be sequentially described.

—Radical Photopolymerization Initiator—

The radical photopolymerization initiator may be a compound that generates a radical as an active species by light irradiation, and known radical photopolymerization initiators can be used without limitation. Specific examples thereof include acetophenones such as diethoxyacetophenone, 2-hydroxy-2methyl-1-phenylpropan-1-one, benzyl dimethyl ketal, 4-(2-hydroxyethoxy)phenyl-(2-hydroxy-2-propyl)ketone, 1-hydroxycyclohexyl phenyl ketone, 2-methyl-2-morpholino(4-thiomethylphenyl)propan-1-one, 2-benzyl-2-dimethylamino-1-(4-morpholinophenyl)butane, 2-hydroxy-2-methyl-1-[4-(1-methyl)phenyl]propane oligomer, and 2-hydroxy-1-{4-[4-(2-hydroxy-2-methyl-propionyl)-benzyl]phenyl}-2-methyl-propan-1-one; oxime esters such as 1,2-octanedione, 1-[4-(phenylthio)-,2-(O-benzoyloxime)], and ethanone,1-[9-ethyl-6-(2-methylbenzoyl)-9H-carbazol-3yl]-, -1-(0-acetyloxime); benzoins such as benzoin, benzoin methyl ether, benzoin ethyl ether, benzoin isopropyl ether, and benzoin isobutyl ether; benzophenones such as benzophenone, methyl o-benzoyl benzoate, 4-phenylbenzophenone, 4-benzoyl-4′-methyl-diphenyl sulfide, 3,3′4,4′-tetra(t-butylperoxycarbonyl)benzophenone, 2,4,6-trimethylbenzophenone, 4-benzoyl-N,N-dimethyl-N-[2-(1-oxo-2-propenyloxy)ethyl]benzene methanaminium bromide, and (4-benzoylbenzyl)trimethyl ammonium chloride; thioxanthones such as 2-isopropylthioxanthone, 4-isopropylthioxanthone, 2,4-diethylthioxanthone, 2,4-dichlorothioxanthone, 1-chloro-4-propoxythioxanthone, 2-(3-dimethylamino-2-hydroxy)-3,4-dimethyl-9H-thioxanthone-9-one methochloride; acylphosphine oxides such as 2,4,6-trimethylbenzoyl-diphenylphosphine oxide, bis(2,6-dimethoxybenzoyl)-2,4,4-trimethyl-pentylphosphine oxide, and bis(2,4,6-trimethylbenzoyl)-phenylphosphine oxide; and the like. Furthermore, as an aid for the radical photopolymerization initiator, triethanolamine, triisopropanolamine, 4,4′-dimethylaminobenzophenone (Michler's ketone), 4,4′-diethylaminobenzophenone, 2-dimethylaminoethyl benzoate, ethyl 4-dimethylaminobenzoate, (n-butoxy)ethyl 4-dimethylaminobenzoate, isoamyl 4-dimethylaminobenzoate, 2-ethylhexyl 4-dimethylaminobenzoate, 2,4-diethylthioxanthone, 2,4-diisopropylthioxanthone, and the like may be used in combination.

The aforementioned radical photopolymerization initiators and aids can be synthesized by a known method or can be obtained as commercially available products. Preferred examples of commercially available radical photopolymerization initiators include IRGACURE manufactured by BASF SE (127, 651, 184, 819, 907, 1870 (initiator as a mixture of CGI-403/Irg 184=7/3, 500, 369, 1173, 2959, 4265, 4236, and the like) OXE 01), KAYACURE manufactured by Nippon Kayaku Co., Ltd. (DETX-S, BP-100, BDMK, CTX, BMS, 2-EAQ, ABQ, CPTX, EPD, ITX, QTX, BTC, MCA, and the like), Esacure manufactured by SARTOMER (KIP 100F, KB1, EB3, BP, X33, K1046, KT37, KIP 150, TZT), and the like.

The mass of the radical photopolymerization initiator contained in the active energy ray-curable resin composition may be appropriately adjusted within a range in which the polymerization reaction (radical polymerization) of the radically polymerizable compound excellently proceeds, and is not particularly limited. The mass of the radical photopolymerization initiator contained in the composition with respect to 100 parts by mass of the radically polymerizable compound contained in the active energy ray-curable resin composition (in a case where the composition contains a radically polymerizable compound that does not correspond to the aforementioned polyfunctional (meth)acrylate, a total of 100 parts by mass of the radically polymerizable compound and the aforementioned polyfunctional (meth)acrylate contained in the active energy ray-curable resin composition) is for example within a range of 0.1 to 20 parts by mass, preferably within a range of 0.5 to 10 parts by mass, and more preferably within a range of 1 to 10 parts by mass).

—Cationic Photopolymerization Initiator—

As the cationic photopolymerization initiator, a compound which can generate a cation as an active species by light irradiation is preferable, and known cationic photopolymerization initiators can be used without limitation. Specific examples thereof include a sulfonium salt, an ammonium salt, an iodonium salt (for example, a diaryl iodonium salt), a triaryl sulfonium salt, a diazonium salt, an iminium salt, and the like that are known. More specifically, examples thereof include the cationic photopolymerization initiators represented by Formulae (25) to (28) shown in paragraphs “0050” to “0053” in JP1996-143806A (JP-H08-143806A), the compounds exemplified as cationic polymerization catalysts in paragraph “0020” in JP1996-283320A (JP-H08-283320A), and the like. The cationic photopolymerization initiator can be synthesized by a known method, or can be obtained as a commercially available product. Examples of the commercially available product include CI-1370, CT-2064, CI-2397, CI-2624, CI-2639, CI-2734, CI-2758, CI-2823, CI-2855, CI-5102, and the like manufactured by NIPPON SODA CO., LTD., PHOTOINITIATOR 2047 and the like manufactured by Rhodia, UVI-6974 and UVI-6990 manufactured by Union Carbide Corporation, CPI-10P manufactured by San-Apro Ltd., and the like.

In view of the sensitivity of the photopolymerization initiator with respect to light, the compound stability, and the like, a diazonium salt, an iodonium salt, a sulfonium salt, and an iminium salt are preferable as the cationic photopolymerization initiator. In view of weather fastness, an iodonium salt is most preferable.

Specific examples of commercially available products of the iodonium salt-based cationic photopolymerization initiator include B2380 manufactured by TOKYO CHEMICAL INDUSTRY CO., LTD., BBI-102 manufactured by Midori Kagaku Co., Ltd., WPI-113 manufactured by Wako Pure Chemical Industries, Ltd., WPI-124 manufactured by Wako Pure Chemical Industries, Ltd., WPI-169 manufactured by Wako Pure Chemical Industries, Ltd., WPI-170 manufactured by Wako Pure Chemical Industries, Ltd., and DTBPI-PFBS manufactured by Toyo Gosei Co., Ltd.

Specific examples of iodonium salt compounds which can be used as the cationic photopolymerization initiator include the following compounds PAG-1 and PAG-2.

Cationic photopolymerization initiator (iodonium salt compound) PAG-1

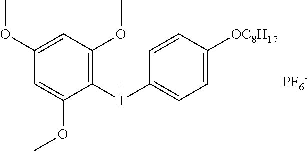

Cationic photopolymerization initiator (iodonium salt compound) PAG-2

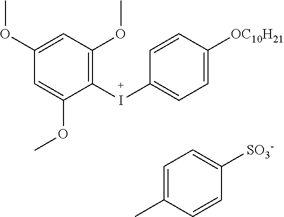

The mass of the cationIC photopolymerization initiator contained in the aforementioned active energy ray-curable resin composition may be appropriately adjusted within a range in which the polymerization reaction (cationic polymerization) of the cationically polymerizable compound excellently proceeds, and is not particularly limited. The mass of the cationic photopolymerization initiator contained in the composition with respect to 100 parts by mass of the cationically polymerizable compound is for example within a range of 0.1 to 200 parts by mass, preferably within a range of 1 to 150 parts by mass, and more preferably within a range of 2 to 100 parts by mass.

As other photopolymerization initiators, it is possible to use the photopolymerization initiators described in paragraphs “0052” to “0055” in JP2009-204725A, and the content of the publication is incorporated into the present specification.

—Antifoulant—

It is preferable that the cured layer or the active energy ray-curable resin composition contains an antifoulant, because then the adhesion of finger print or contaminant is suppressed, the contaminant that has adhered can be wiped off in a simple way, and scratch resistance can be improved by enhancing sliding properties of the surface of the cured layer. The antifoulant will be referred to as g) component as well.

The antifoulant preferably contains a fluorine-containing compound, the fluorine-containing compound preferably has a perfluoropolyether group and polymerizable unsaturated groups, and the antifoulant has a plurality of polymerizable unsaturated groups in one molecule.

As the antifoulant usable in the present invention, it is possible to use the materials described in paragraphs “0012” to “0101” in JP2012-088699A, and the content of the publication is incorporated into the present specification.

As the antifoulant described so far, those synthesized by known methods or commercially available products may be used. As commercially available products, RS-90 and RS-78 manufactured by DIC Corporation and the like can be preferably used. In view of scratch resistance, RS-90 manufactured by DIC Corporation can be more preferably used.

—Solvent—

As the solvent which can be contained in the composition as an optional component, an organic solvent is preferable. One kind of organic solvent can be used, or two or more kinds of organic solvents can be used by being mixed together at any ratio. Specific examples of the organic solvent include alcohols such as methanol, ethanol, propanol, n-butanol, and i-butanol; ketones such as acetone, methyl isobutyl ketone, methyl ethyl ketone, and cyclohexanone; cellosolves such as ethyl cellosolve; aromatic solvents such as toluene and xylylene; glycol ethers such as propylene glycol monomethyl ether; acetic acid esters such as methyl acetate, ethyl acetate, and butyl acetate; diacetone alcohol; and the like. The amount of the solvent in the aforementioned active energy ray-curable resin composition can be appropriately adjusted within a range in which coating suitability of the active energy ray-curable resin composition can be secured. For example, the content of the solvent in the composition with respect to a total of 100 parts by mass of the polymerizable compound and the photopolymerization initiator can be 50 to 500 parts by mass, and preferably 80 to 200 parts by mass.

<Optional Layer>

The hardcoat film according to the present invention may optionally include one or more other layers, in addition to the base material film and the cured layer. Examples of the optional layers include, but are not limited to, an easy-adhesive layer, an antireflection layer (laminated film consisting of one or more layers of high refractive index and one or more layers of low refractive index), and the like. Regarding these layers, for example, paragraphs “0069” to “0091” and the like in JP5048304B can be referred to. Furthermore, a touch sensor film, a polarizer, a decorative layer may also be provided.

(Layer of Low Refractive Index)

In a case where the hardcoat film of the present invention is used as an antireflection film, an aspect is also preferable in which a single or a plurality of antireflection layers are laminated on the surface of the cured layer. The constitution of an antireflection layer which can be preferably used in the present invention will be shown below.

A: base material film/cured layer/layer of low refractive index

B: base material film/cured layer/layer of high refractive index/layer of low refractive index

C: base material film/cured layer/layer of medium refractive index/layer of high refractive index/layer of low refractive index

In the hardcoat film of the present invention, it is preferable that a layer of low refractive index is disposed on the cured layer directly or through another layer.

Paragraphs “0077” to “0102” in JP2009-204725A describe preferred aspects of the layer of low refractive index, and the content of the publication is incorporated into the present specification.

In the hardcoat film of the present invention, by providing a layer having a high refractive index (layer of high refractive index or a layer of medium refractive index) between the layer of low refractive index and the cured layer, antireflection properties can be improved. The layer of high refractive index and the layer of medium refractive index are collectively called a layer of high refractive index in some cases. “High”, “medium”, and “low” for the layer of high refractive index, the layer of medium refractive index, and the layer of low refractive index show the relationship between the layers based on the relative magnitude of the refractive index thereof. Furthermore, regarding the relationship with the base material film based on the refractive index, it is preferable that a relationship of base material film>layer of low refractive index and a relationship of layer of high refractive index>base material film are satisfied.

In the present specification, the layer of high refractive index, the layer of medium refractive index, and the layer of low refractive index are collectively called an antireflection layer in some cases. Paragraphs “0103” to “0112” in JP2009-204725A describe preferred aspects of the layer of high refractive index, and the content of the publication is incorporated into the present specification.

(Touch Sensor Film)

It is preferable that the hardcoat film of the present invention has a touch sensor film on a surface of the base material film that is opposite to a surface of the base material film on which the cured layer is disposed. That is, it is preferable that a touch sensor film is bonded to a surface of the base material film that is opposite to a surface of the base material film on which the cured layer is disposed.

The touch sensor film is not particularly limited, but is preferably a conductive film in which a conductive layer is formed.

The conductive film preferably includes any support and a conductive layer disposed on the support.

The material of the conductive layer is not particularly limited, and examples thereof include an indium.tin composite oxide (Indium Tin Oxide; ITO), tin oxide, antimony tin oxide (ATO), copper, silver, aluminum, nickel, chromium., an alloy of these, and the like.

The conductive layer is preferably an electrode pattern. Furthermore, the conductive layer is also preferably a transparent electrode pattern. The electrode pattern may be obtained by forming a layer of a transparent conductive material by patterning or obtained by forming a layer of a non-transparent conductive material by patterning.

As the transparent conductive material, it is possible to use an oxide such as ITO or ATO, silver nanowires, carbon nanotubes, a conductive polymer, and the like.

Examples of the layer of a non-transparent conductive material include a metal layer. As the metal layer, any metal having conductivity can be used, and silver, copper, gold, aluminum, and the like are suitably used. The metal layer may be a simple metal or an alloy, or may be a layer in which metal particles are bonded to each other through a binder. If necessary, the surface of the metal may be subjected to a blackening treatment or a rust-proofing treatment. In a case where a metal is used, a sensor portion that is substantially transparent and a peripheral wiring portion can be collectively formed.

It is preferable that the conductive layer contains a plurality of metal thin wires.

The metal thin wires are preferably formed of silver or an alloy containing silver. The conductive layer containing metal thin wires formed of silver or an alloy containing silver is not particularly limited, and known conductive layers can be used. For example, it is preferable to use the conductive layer described in paragraphs “0040” and “0041” in JP2014-168886A, and the content of the publication is incorporated into the present specification.

It is also preferable that the metal thin wires are formed of copper or an alloy containing copper. The conductive layer containing metal thin wires formed of copper or an alloy containing copper is not particularly limited, and known conductive layers can be used. For example, it is preferable to use the conductive layer described in paragraphs “0038” to “0059” in JP2015-49852A, and the content of the publication is incorporated into the present specification.

It is also preferable that the conductive layer is formed of an oxide. In a case where the conductive layer is formed of an oxide, it is more preferable that the oxide is formed of indium oxide containing tin oxide or of tin oxide containing antimony. The conductive layer formed of an oxide is not particularly limited, and known conductive layers can be used. For example, it is preferable to use the conductive layer described in paragraphs “0017” to “0037” in JP2010-27293A, and the content of the publication is incorporated into the present specification.

Among these conductive layer constituted as above, a conductive layer is preferable which contains a plurality of metal thin wires that are disposed in a mesh shape or a random shape, and a conductive layer is more preferable in which the metal thin wires are disposed in a mesh shape. Particularly, a conductive layer is preferable in which the metal thin wires are disposed in a mesh shape and formed of a silver or an alloy containing silver.

It is also preferable that the touch sensor film has a conductive layer on both surfaces thereof.

Paragraphs “0016” to “0042” in JP2012-206307A describe preferred aspects of the touch sensor film, and the content of the publication is incorporated into the present specification.

(Polarizer)

It is preferable that the hardcoat film of the present invention has a polarizer on a surface of the base material film that is opposite to a surface of the base material film on which the cured layer is disposed. That is, it is preferable that the polarizer is bonded to a surface of the base material film that is opposite to a surface of the base material film on which the cured layer is disposed.

The hardcoat film of the present invention is used on one side or both sides of a protect film of a polarizing plate including a polarizer and a protect film disposed on both sides of the polarizer, and in this way, a polarizing plate having a hardcoat properties can be obtained.

It is preferable to be able to provide a polarizing plate which has the hardcoat film of the present invention, has ameliorated brittleness, is excellent in handleability, does not impair display quality by surface smoothness or wrinkles, and can suppress the leakage of light at the time of moist-heat test.

The hardcoat film of the present invention may be used as a protect film for one side, and a general cellulose acetate film may be used as a protect film for the other side. As the protect film for the other side, it is preferable to use a cellulose acetate film which is manufactured by a solution film forming method and stretched along a width direction (direction parallel to the shaft of a roll) in a roll film form at a stretching ratio of 10% to 100%.

An aspect is also preferable in which, of the two sheets of the protect films of the polarizer, the film other than the hardcoat film of the present invention is an optical compensation film having an optical compensation layer including an optically anisotropic layer. The optical compensation film (phase difference film) can improve the viewing angle characteristics of a liquid crystal display screen. As the optical compensation film, known optical compensation films can be used, but in view of widening the viewing angle, the optical compensation film described in JP2001-100042A is preferable.

The polarizer includes an iodine-based polarizer, a dye-based polarizer using a dichroic dye, and a polyene-based polarizer. The iodine-based polarizer and the dye-based polarizer are generally manufactured using a polyvinyl alcohol-based film.

As the polarizer, a known polarizer or a polarizer cut out from a long polarizer whose absorption axis is neither parallel nor perpendicular to the longitudinal direction may be used. The long polarizer whose absorption axis is neither parallel nor perpendicular to the longitudinal direction is manufactured by the following method.

The polarizer can be manufactured by a stretching method in which, in a state where both ends of a continuously supplied polymer film such as a polyvinyl alcohol-based film are being held by holding means, the film is stretched under a tension applied thereto such that the film is stretched by a factor of 1.1 to 20.0 in at least the film width direction; a difference in a moving rate between the holding devices at both ends of the film in the longitudinal direction is made within 3%; and the moving direction of the film is bent in a state where both ends of the film are being held, such that the moving direction of the film at the exit of the step of holding both ends of the film and the actual stretching direction of the film form an oblique angle of 20° to 70°. From the viewpoint of productivity, it is preferable that an oblique angle of 45° is formed between the moving direction of the film at the exit of the step of holding both ends of the film and the actual stretching direction of the film.

The stretching method of the polymer film is specifically described in paragraphs “0020” to “0030” in JP2002-86554A.

<Articles Including Hardcoat Film>

Examples of articles including the hardcoat film of the present invention include various articles required to be improved in terms of scratch resistance in various industrial fields such as the field of home appliances, the field of electricity and electronics, the field of automobiles, and the field of housing. Specifically, examples of such articles include a touch sensor, a touch panel, an image display such as a liquid crystal display, window glass of automobiles, window glass for home, and the like. By providing the hardcoat film of the present invention (preferably as a surface protect film) in these articles, it is possible to provide articles having excellent scratch resistance. It is preferable that the hardcoat film of the present invention is a hardcoat film for front plate of a touch panel.

[Front Plate of Image Display Element]

The front plate of an image display element of the present invention is a front plate of an image display element containing the hardcoat film of the present invention. As described above, in a case where the hardcoat film of the present invention is provided as a surface protect film of an image display, the hardcoat film of the present invention can be used as a front plate of an image display element. Furthermore, in a case where the hardcoat film is provided as a cover plastic as a substitute for cover glass that has been used in the related art as a front plate of a touch panel, the hardcoat film of the present invention can also be used as front plate of an image display element.

The touch panel in which the front plate of an image display element of the present invention can be used is not particularly limited, and can be appropriately selected according to the purpose. Examples of the touch panel include a surface capacitance-type touch panel, a projected capacitance-type touch panel, a resistive film-type touch panel, and the like. Details of the touch panel will be specifically described later by using the resistive film-type touch panel and the capacitance-type touch panel of the present invention.

The touch panel includes so-called touch sensor and touch pad. In the touch panel, the layer constitution of a touch panel sensor electrode portion may be established by any of a bonding method in which two sheets of transparent electrodes are bonded to each other, a method of providing a transparent electrode on both surfaces of one sheet of substrate, a method using a single-face jumper or a through hole, and a single-face lamination method. Furthermore, for the projected capacitance-type touch panel, alternating current (AC) driving is more preferred than direct current (DC) driving, and a driving method in which voltage is applied to the electrode for a short period of time is more preferable.

[Resistive Film-Type Touch Panel]

The resistive film-type touch panel of the present invention includes the front plate an image display element of the present invention.

Basically, the resistive film-type touch panel has a constitution in which conductive layers of a pair of upper and lower substrates each having a conductive layer are disposed with a spacer therebetween such that the conductive layers face each other. The constitution of the resistive film-type touch panel is known, and in the present invention, known techniques can be adopted without any limitation.

[Capacitance-Type Touch Panel]

The capacitance-type touch panel of the present invention includes the front plate of an image display element of the present invention.

Examples of the capacitance-type touch panel include a surface capacitance-type touch panel, a projected capacitance-type touch panel, and the like. Basically, the projected capacitance-type touch panel has a constitution in which an X-axis electrode and a Y-axis electrode orthogonal to the X-axis electrode are disposed with an insulating material therebetween. Examples of specific aspects thereof include an aspect in which an X-axis electrode and a Y-axis electrode are formed on different surfaces of one sheet of substrate, an aspect in which an X-axis electrode, a layer of an insulating material, and a Y-axis electrode are formed in this order on one sheet of substrate, an aspect in which an X-axis electrode is formed on one sheet of substrate while a Y-axis electrode is formed on the other substrate (in this aspect, a constitution in which two sheets of substrates are bonded to each other is adopted as the aforementioned basic constitution), and the like. The constitution of the capacitance-type touch panel is known, and in the present invention, known techniques can be adopted without any limitation.

[Image Display]

The image display of the present invention includes the front plate of the image display element and the image display element of the present invention.

The front plate of an image display element of the present invention can be used in image displays such as a liquid crystal display (LCD), a plasma display panel, an electroluminescence display, and a cathode tube display. Examples of the liquid crystal display include a twisted nematic (TN) type, a super-twisted nematic (STN) type, a triple super twisted nematic (TSTN) type, a multi domain type, a vertical alignment (VA) type, an in-plane switching (IPS) type, an optically compensated bend (OCB) type, and the like.

According to the present invention, it is preferable to be able to provide an image display which has the front plate of an image display element of the present invention, has ameliorated brittleness, is excellent in handleability, does not impair display quality by surface smoothness or wrinkles, and can suppress the leakage of light at the time of moist-heat test.

The image display is particularly preferably a liquid crystal display including a liquid crystal cell and the polarizing plate of the present invention disposed on at least one surface of the liquid crystal cell, in which the hardcoat film of the present invention is disposed on the uppermost surface of the liquid crystal display. That is, in the image display of the present invention, the image display element is preferably a liquid crystal display element.

In the image display of the present invention, the image display element is also preferably an organic electroluminescence display element.

In the image display of the present invention, the image display element is preferably an in-cell touch panel display element. The in-cell touch panel display element is an element in which a touch panel function is included in a cell of an image display element.

In the in-cell touch panel display element, for example, the known techniques described in JP2011-76602A, JP2011-222009A, and the like can be adopted without any limitation.

Furthermore, in the image display of the present invention, the image display element is also preferably an on-cell touch panel display element. The on-cell touch panel display element is an element in which a touch panel function is on the outside of a cell of an image display element.

In the on-cell touch panel display element, for example, the known techniques described in JP2012-88683A and the like can be adopted without any limitation.

### EXAMPLES

Hereinafter, the present invention more specifically described based on examples and comparative examples. The materials and the amount and proportion thereof used, the content of a treatment, the sequence of a treatment, and the like shown in the following examples can be appropriately changed within a range that does not depart from the gist of the present invention. Accordingly, the scope of the present invention is not limited to the specific examples described below.

### Examples 1 to 27, Comparative Examples 1 to 3, and Reference Examples 1 and 2

<Type of Inorganic Fine Particles and Matt Particles and Measurement of Particle Diameter>

As inorganic fine particles, ELCOM V-8802 (dispersion liquid of spherical silica particles having an average primary particle diameter of 15 mn manufactured by JGC CORPORATION, solid content of SiO₂: 40.8% by mass), MEK-AC-4130 (manufactured by NISSAN CHEMICAL INDUSTRIES, LTD., methyl ethyl ketone dispersion liquid of spherical silica particles having an average primary particle diameter of 45 nm, solid content of SiO₂: 30% by mass), and MEK-AC-5140Z (manufactured by NISSAN CHEMICAL INDUSTRIES, LTD., methyl ethyl ketone dispersion liquid of spherical silica particles having an average primary particle diameter of 85 nm, solid content of SiO₂: 40% by mass) were used.

As matt particles, cross-linked methyl methacrylate polymer particles were used which were prepared to have average primary particle diameters of 1.5 μm, 2 μm, 4 μm, 6 μm, 10 μm, 14 μm, and 20 μm (manufactured by SEKISUI PLASTICS CO., LTD.).

Any method can be used as a method for measuring the average primary particle diameter of the inorganic fine particles and the matt particles, as long as the method is for measuring an average primary particle diameter of particles. Examples of the method include a method of measuring a particle size distribution of particles by a Coulter counter method and calculating the average primary particle diameter from a particle distribution obtained by expressing the measured particle distribution in terms of a distribution of number of particles, and a method of observing one hundred particles using a transmission electron microscope (500,000× to 2,000,000× magnification) and determining an average primary particle diameter based on the average particle diameter of the particles.

For the aforementioned inorganic fine particles and matt particles used in examples, the average of primary particle diameters of one hundred particles that is determined from an electron micrograph is taken as an average primary particle diameter.

By using a transmission electron microscope, it was confirmed that the inorganic fine particles used are present in the cured layer, in a non-spherical shape in which two to ten spherical inorganic fine particles are linked to each other.

<Type of Polyrotaxane and Other Polymers and Measurement of Weight-Average Molecular Weight>

As polyrotaxane, among those in a SeRM super polymer series manufactured by Advanced Softmaterials Inc., PR1, PR2, PR3, and PR4 described in the following Table 1 were used.

In comparative example, as another polymer, polyester urethane UR-3210 (manufactured by Toyoho Co., Ltd, weight-average molecular weight: 400,000) was used.

TABLE 1

| | | Unsaturated double bond group | | |
|---|---|---|---|---|
| | | Methacryloyl | Acryloyl | Weight-average |
| Polyrotaxane | Trade name | group | group | molecular weight |
| PR1 | SM1315P | Present | Absent | 180,000 |
| PR2 | SH1310P | Absent | Absent | 180,000 |
| PR3 | SA1315P | Absent | Present | 190,000 |
| PR4 | SM3405P | Present | Absent | 1,000,000 |

PR1~4 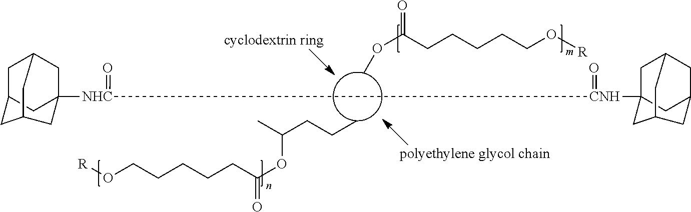
SM1315P, SM3405P: R = H or 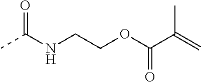
SH1310P: R = H
SA1315P: R = H or

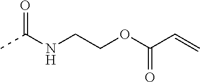

In the present invention and the present specification, unless otherwise specified, for a multimer, a molecular weight refers to a weight-average molecular weight measured by gel permeation chromatography (GPC) and expressed in terms of polystyrene. In examples, as specific measurement conditions for the weight-average molecular weight of polyrotaxane and other polymers, the following measurement conditions were used.

GPC device: HLC-8120 (manufactured by Tosoh Corporation):

Column: TSK gel Multipore HXL-M (manufactured by Tosoh Corporation, 7.8 mmID (inside diameter)×30.0 cm)

Eluent: tetrahydrofuran (THF)

Preparation of Active Energy Ray-Curable Resin Composition>

The components were mixed together according to the composition shown in the following Tables 2 and 3 and filtered through a filter made of polypropylene having a pore size of 30 μm, thereby preparing active energy ray-curable resin compositions (compositions for forming a cured layer) HC1 to HC27. For the components excluding a solvent, the numerical values shown in the following Tables 2 and 3 show “proportion (% by mass) in a total solid content” of each component. For example, for EL COM V-8802 as a dispersion liquid of silica particles used as inorganic fine particles, the amount thereof expressed in terms of the amount of the solid content of the silica particles (not the mass of the dispersion liquid) is shown in the following Tables 2 and 3.

Other compounds used in the active energy ray-curable resin composition will be shown below.

(Polymerizable Compound)

DPHA: “DPHA” as mixture of dipentaerythritol pentaacrylate and dipentaerythritol hexaacrylate (manufactured by Nippon Kayaku Co., Ltd.)

CYCLOMER M-100: 3,4-epoxycyclohexylmethyl methacrylate (manufactured by DAICEL CORPORATION)

(Photopolymerization Initiator)

IRG 184 (IRGACURE 184, radical photopolymerization initiator based on 1-hydroxy-cyclohexyl-phenyl-ketone, α-hydroxyalkylphenone, manufactured by BASF SE)

PAG-1 (cationic photopolymerization initiator based on iodonium salt)

(Antifoulant)

RS-90: manufactured by DIC Corporation

For solvents, the solvent ratio was adjusted such that the ratio shown in the following Tables 2 and 3 was established, and in this way, active energy ray-curable resin compositions having a solid content ratio described in the following Table 2 were obtained.

<Formation of Cured Layer>

As a base material film, TECHNOLLOY C101 manufactured by Escarbo Sheet Company; Ltd was prepared in which polymethyl methacrylate (PMMA), polycarbonate (PC), and polymethyl methacrylate (PMMA) were laminated in this order. The total film thickness of TECHNOLLOY C101 was 300 μM, the film thickness of PMMA was 70 μm, and the pencil hardness was 2H. Other base material films used in other examples will be described later.

One surface of the base material film was coated with the active energy ray-curable resin composition, and the film thickness was adjusted such that the film thickness of the cured layer having undergone a curing treatment (light irradiation) became as shown in the following Tables 4 and 5, thereby preparing a hardcoat film (base material film with a cured layer).

Specifically, by a die coating method using a slot die which is used in examples of JP2006-122889A and shown in paragraph “0486” and FIG. 10 of JP2006-122889A, one surface of the base material film was coated with the active energy ray-curable resin composition under the condition of a transport speed of 30 m/min, and the composition was dried for 150 seconds at 60° C. Then, with nitrogen purging at an oxygen concentration of about 0.1% by volume, by using an air-cooled metal halide lamp (manufactured by EYE GRAPHICS Co., Ltd.) at 160 W/cm, the coating layer was cured by being irradiated with ultraviolet rays at an illuminance of 400 mW/cm² and an irradiation amount of 500 mJ/cm², thereby forming a cured layer. Thereafter, the obtained laminate of the base material film and the cured film was wound up, thereby preparing hardcoat films (front plates of an image display element) of Examples 1 to 27, Comparative Examples 1 to 3, and Reference Examples 1 and 2.

In Tables 4 and 5, “wt %” means % by mass.

TABLE 2

| Active energy ray-curable resin composition | | HC1 | HC2 | HC3 | HC4 | HC5 | HC6 | HC7 | HC8 |
|---|---|---|---|---|---|---|---|---|---|
| Polymerizable | DPHA | 29.0% | 34.0% | 24.0% | 14.0% | 4.0% | 48.0% | 44.0% | 39.0% |
| compound | CYCLOMER M100 | 15.0% | 15.0% | 15.0% | 15.0% | 15.0% | 5.0% | 15.0% | 15.0% |
| Polyrotaxane | PR1 | 20.0% | 20.0% | 20.0% | 20.0% | 20.0% | 1.0% | 5.0% | 10.0% |
| | PR2 | | | | | | | | |
| | PR3 | | | | | | | | |
| | PR4 | | | | | | | | |
| Polyester urethane | UR-3210 | | | | | | | | |
| Matt particles | Average primary particle | | | | | | | | |
| | diameter 1.5 μm, acryl particles | | | | | | | | |
| | Average primary particle | | | | | | | | |
| | diameter 2 μm, acryl particles | | | | | | | | |
| | Average primary particle | | | | | | | | |
| | diameter 4 μm, acryl particles | | | | | | | | |
| | Average primary particle | 15.0% | 10.0% | 20.0% | 30.0% | 40.0% | 15.0% | 15.0% | 15.0% |
| | diameter 6 μm, acryl particles | | | | | | | | |
| | Average primary particle | | | | | | | | |
| | diameter 10 μm, acryl particles | | | | | | | | |
| | Average primary particle | | | | | | | | |
| | diameter 14 μm, acryl particles | | | | | | | | |
| | Average primary particle | | | | | | | | |
| | diameter 20 μm, acryl particles | | | | | | | | |
| Inorganic | ELCOM V-8802 | 15.0% | 15.0% | 15.0% | 15.0% | 15.0% | 15.0% | 15.0% | 15.0% |
| fine | MEK-AC-4130 | | | | | | | | |
| particles | MEK-AC-5140Z | | | | | | | | |
| Photopolymerization | Irg184 | 4.0% | 4.0% | 4.0% | 4.0% | 4.0% | 4.0% | 4.0% | 4.0% |
| initiator | PAG-1 | 1.0% | 1.0% | 1.0% | 1.0% | 1.0% | 1.0% | 1.0% | 1.0% |
| Antifoulant | RS-90 | 1.0% | 1.0% | 1.0% | 1.0% | 1.0% | 1.0% | 1.0% | 1.0% |
| Solvent | Methyl ethyl ketone | 40% | 40% | 40% | 40% | 40% | 40% | 40% | 40% |
| | Methyl isobutyl ketone | 60% | 60% | 60% | 60% | 60% | 60% | 60% | 60% |

| | | | | | | | | |
|---|---|---|---|---|---|---|---|---|
| Ratio of total solid content | 60% | 60% | 60% | 60% | 60% | 60% | 60% | 60% |

| Active energy ray-curable resin composition | | HC9 | HC10 | HC11 | HC12 | HC13 | HC14 | HC15 |
|---|---|---|---|---|---|---|---|---|
| Polymerizable | DPHA | 19.0% | 9.0% | 29.0% | 29.0% | 29.0% | 29.0% | 29.0% |
| compound | CYCLOMER M100 | 15.0% | 15.0% | 15.0% | 15.0% | 15.0% | 15.0% | 15.0% |
| Polyrotaxane | PR1 | 30.0% | 40.0% | 20.0% | 20.0% | 20.0% | 20.0% | 20.0% |
| | PR2 | | | | | | | |
| | PR3 | | | | | | | |
| | PR4 | | | | | | | |
| Polyester urethane | UR-3210 | | | | | | | |
| Matt particles | Average primary particle | | | | | | | |
| | diameter 1.5 μm, acryl particles | | | | | | | |
| | Average primary particle | | | 15.0% | | | | |
| | diameter 2 μm, acryl particles | | | | | | | |
| | Average primary particle | | | | 15.0% | | | |
| | diameter 4 μm, acryl particles | | | | | | | |
| | Average primary particle | 15.0% | 15.0% | | | | | |
| | diameter 6 μm, acryl particles | | | | | | | |
| | Average primary particle | | | | | 15.0% | | |
| | diameter 10 μm, acryl particles | | | | | | | |
| | Average primary particle | | | | | | 15.0% | |
| | diameter 14 μm, acryl particles | | | | | | | |
| | Average primary particle | | | | | | | 15.0% |
| | diameter 20 μm, acryl particles | | | | | | | |
| Inorganic | ELCOM V-8802 | 15.0% | 15.0% | 15.0% | 15.0% | 15.0% | 15.0% | 15.0% |
| fine | MEK-AC-4130 | | | | | | | |
| particles | MEK-AC-5140Z | | | | | | | |
| Photopolymerization | Irg184 | 4.0% | 4.0% | 4.0% | 4.0% | 4.0% | 4.0% | 4.0% |
| initiator | PAG-1 | 1.0% | 1.0% | 1.0% | 1.0% | 1.0% | 1.0% | 1.0% |
| Antifoulant | RS-90 | 1.0% | 1.0% | 1.0% | 1.0% | 1.0% | 1.0% | 1.0% |
| Solvent | Methyl ethyl ketone | 40% | 40% | 40% | 40% | 40% | 40% | 40% |
| | Methyl isobutyl ketone | 60% | 60% | 60% | 60% | 60% | 60% | 60% |

| | | | | | | | |
|---|---|---|---|---|---|---|---|
| Ratio of total solid content | 60% | 60% | 60% | 60% | 60% | 60% | 60% |

TABLE 3

| Active energy ray-curable resin composition | | HC16 | HC17 | HC18 | HC19 | HC20 | HC21 | HC22 |
|---|---|---|---|---|---|---|---|---|
| Polymerizable | DPHA | 29.0% | 29.0% | 39.0% | 14.0% | 4.0% | 29.0% | 29.0% |
| compound | CYCLOMER M100 | 15.0% | 15.0% | 15.0% | 15.0% | 15.0% | 15.0% | 15.0% |
| Polyrotaxane | PR1 | 20.0% | 20.0% | 20.0% | 20.0% | 20.0% | | |
| | PR2 | | | | | | 20.0% | |
| | PR3 | | | | | | | 20.0% |
| | PR4 | | | | | | | |
| Polyester urethane | UR-3210 | | | | | | | |
| Matt particles | Average primary particle | | | | | | | |
| | diameter 1.5 μm, acryl particles | | | | | | | |
| | Average primary particle | | | | | | | |
| | diameter 2 μm, acryl particles | | | | | | | |
| | Average primary particle | | | | | | | |
| | diameter 4 μm, acryl particles | | | | | | | |
| | Average primary particle | 15.0% | 15.0% | 15.0% | 15.0% | 15.0% | 15.0% | 15.0% |
| | diameter 6 μm, acryl particles | | | | | | | |
| | Average primary particle | | | | | | | |
| | diameter 10 μm, acryl particles | | | | | | | |
| | Average primary particle | | | | | | | |
| | diameter 14 μm, acryl particles | | | | | | | |
| | Average primary particle | | | | | | | |
| | diameter 20 μm, acryl particles | | | | | | | |
| Inorganic | ELCOM V-8802 | | | 5.0% | 30.0% | 40.0% | 15.0% | 15.0% |
| fine | MEK-AC-4130 | 15.0% | | | | | | |
| particles | MEK-AC-5140Z | | 15.0% | | | | | |
| Photopolymerization | Irg184 | 4.0% | 4.0% | 4.0% | 4.0% | 4.0% | 4.0% | 4.0% |
| initiator | PAG-1 | 1.0% | 1.0% | 1.0% | 1.0% | 1.0% | 1.0% | 1.0% |
| Antifoulant | RS-90 | 1.0% | 1.0% | 1.0% | 1.0% | 1.0% | 1.0% | 1.0% |
| Solvent | Methyl ethyl ketone | 40% | 40% | 40% | 40% | 40% | 40% | 40% |
| | Methyl isobutyl ketone | 60% | 60% | 60% | 60% | 60% | 60% | 60% |

| | | | | | | | |
|---|---|---|---|---|---|---|---|
| Ratio of total solid content | 60% | 60% | 60% | 60% | 60% | 60% | 60% |

| Active energy ray-curable resin composition | | HC23 | HC24 | HC25 | HC26 | HC27 |
|---|---|---|---|---|---|---|
| Polymerizable | DPHA | 29.0% | 49.0% | 29.0% | 29.0% | 64.0% |
| compound | CYCLOMER M100 | 15.0% | 15.0% | 15.0% | 15.0% | 15.0% |
| Polyrotaxane | PR1 | | | | 20.0% | |
| | PR2 | | | | | |
| | PR3 | | | | | |
| | PR4 | 20.0% | | | | |
| Polyester urethane | UR-3210 | | | 20.0% | | |
| Matt particles | Average primary particle | | | | 15.0% | |
| | diameter 1.5 μm, acryl particles | | | | | |
| | Average primary particle | | | | | |
| | diameter 2 μm, acryl particles | | | | | |
| | Average primary particle | | | | | |
| | diameter 4 μm, acryl particles | | | | | |
| | Average primary particle | 15.0% | 15.0% | 15.0% | | 15.0% |
| | diameter 6 μm, acryl particles | | | | | |
| | Average primary particle | | | | | |
| | diameter 10 μm, acryl particles | | | | | |
| | Average primary particle | | | | | |
| | diameter 14 μm, acryl particles | | | | | |
| | Average primary particle | | | | | |
| | diameter 20 μm, acryl particles | | | | | |
| Inorganic | ELCOM V-8802 | 15.0% | 15.0% | 15.0% | 15.0% | |
| fine | MEK-AC-4130 | | | | | |
| particles | MEK-AC-5140Z | | | | | |
| Photopolymerization | Irg184 | 4.0% | 4.0% | 4.0% | 4.0% | 4.0% |
| initiator | PAG-1 | 1.0% | 1.0% | 1.0% | 1.0% | 1.0% |
| Antifoulant | RS-90 | 1.0% | 1.0% | 1.0% | 1.0% | 1.0% |
| Solvent | Methyl ethyl ketone | 40% | 40% | 40% | 40% | 40% |
| | Methyl isobutyl ketone | 60% | 60% | 60% | 60% | 60% |

| | | | | | |
|---|---|---|---|---|---|
| Ratio of total solid content | 60% | 60% | 60% | 60% | 60% |

### Example 28

By the method described in paragraphs “0016” to “0040” in JP2013-206444A, the film sensor described in paragraphs “0026” to “0035” in JP2013-206444A was used as a touch sensor film and bonded to a surface of the base material film of the hardcoat film of Example 1 that was opposite to a surface of the base material film on which the cured layer was disposed, thereby preparing a hardcoat film (a front plate of an image display element and a capacitance-type touch panel) of Example 28.

### Example 29

By using a slot die coater described in FIG. 1 in JP22003-211052A, the cured layer of the hardcoat film of Example 1 was wet-coated with a coating solution for a layer of low refractive index prepared by the following method such that a dry film thickness of a layer of low refractive index became 100 mn, and the coating solution was dried for 50 seconds at 60° C. Then, with nitrogen purging, in an atmosphere with an oxygen concentration of equal to or lower than 100 parts per million (ppm) by volume, the coating solution was irradiated with ultraviolet rays by using an air-cooled metal halide lamp (manufactured by EYE GRAPHICS Co., Ltd.) at 240/cm until the irradiation amount became 400 mJ/cm², thereby forming a layer of low refractive index. Thereafter, the obtained laminate of the base material film, the cured layer, and the layer of low refractive index was wound up, thereby preparing a hardcoat film (a front plate of an image display element) of Example 29.

<Preparation of Coating Solution for Layer of Low Refractive Index>

(Preparation of Sol Liquid A)

120 parts by mass of methyl ethyl ketone, 100 parts by mass of acryloxypropyl trimethoxysilane “KBM-5103” (manufactured by Shin-Etsu Chemical Co., Ltd.), and 3 parts by mass of diisopropoxyaluminum ethyl acetoacetate were put into a reactor equipped with a stirrer and a reflux condenser and mixed together. Then, 30 parts by mass of deionized water was added thereto, a reaction was performed for 4 hours at 60° C., and the reaction solution was cooled to room temperature, thereby obtaining a sol liquid a. The weight-average molecular weight thereof was 1,800, and among the components having a molecular weight equal to or greater than that of an oligomer component, components having a molecular weight of 1,000 to 20,000 had a proportion of 100% by mass. Through glass chromatography, no residue of acryloxypropyl trimethoxysilane as a raw material was confirmed.

(Preparation of Hollow Silica Particle Dispersion Liquid (A-1))

500 parts by mass of hollow silica particle sol (particle diameter: about 40 to 50 nm, shell thickness: 6 to 8 nm, refractive index: 1.31, concentration of solid content: 20% by mass, main solvent: isopropyl alcohol, prepared by changing the particle diameter based on Preparation Example 4 in JP2002-79616A) was mixed with 30 parts by mass of acryloyloxypropyl trimethoxysilane “KBM-5103” (manufactured by Shin-Etsu Chemical Co., Ltd.) and 1.5 parts by mass of diisopropoxyaluminum ethyl acetoacetate “CHELOPE EP-12” (manufactured by Hope Chemical Co., LTD.), and then 9 parts by mass of deionized water was added thereto. The solution was reacted for 8 hours at 60° C. and then cooled to room temperature, and 1.8 parts of acetyl acetone was added thereto, thereby obtaining a hollow silica particle dispersion liquid (A-1). The obtained hollow silica particle dispersion liquid (A-1) had a concentration of solid contents of 18% by mass, and a refractive index thereof measured after drying the solvent was 1.31.

(Preparation of Coating Solution for Layer of Low Refractive Index (LL-1))

44.0 parts by mass of the fluorine-containing copolymer (P-3) (weight-average molecular weight: about 50,000) described in paragraph “0043” in JP2004-45462A, 6.0 parts by mass of “DPHA” (manufactured by Nippon Kayaku Co., Ltd.) as a mixture of dipentaerythritol pentaacrylate and dipentaerythritol hexaacrylate, 3.0 parts by mass of silicone “RMS-033” (manufactured by Gelest, Inc) containing a terminal methacrylate group, and 3.0 parts by mass of “Irgacure 907” (manufactured by BASF SE) were added to 100 parts by mass of methyl ethyl ketone and dissolved. Then, 195 parts by mass (39.0 parts by mass as silica+surface-treated solid contents) of the hollow silica particle dispersion liquid (A-1) and 17.2 parts by mass (5.0 parts by mass as solid contents) of the sol liquid a were added thereto, thereby obtaining a mixed solution. The mixed solution was diluted with cyclohexane and methyl ethyl ketone such that the concentration of solid contents of the entirety of the coating solution became 6% by mass and that a mass ratio of cyclohexane/methyl ethyl ketone became 10/90, thereby preparing a coating solution for a layer of low refractive index (LL-1).

A coating film obtained by coating performed using the coating solution for a layer of low refractive index (LL-1) had a refractive index of 1.38 after curing.

### Example 30

A hardcoat film (a front plate of an image display element) of Example 30 was prepared by the same method as in Example 1, except that as a base material film, a base material film (PMMA/PC/PMMA) constituted with three layers of acrylic resin layer/polycarbonate-based resin layer/acrylic resin layer was prepared by the following method and used instead of TECHNOLLOY C101.

<Preparation of Base Material Constituted with Three Layers>

Pellets of an acrylic resin “SUMIPEX EX” manufactured by Sumitomo Chemical Co., Ltd were put into a single-screw extruder having an extrusion diameter of 65 mm, and a polycarbonate-based resin “CALIBRE 301-10” manufactured by Sumika Styron Polycarbonate Limited was put into a single-screw extruder having an extrusion diameter of 45 mm. The resins were melted, thereby obtaining molten resins. By using a multi-manifold method, the molten resins were integrated by being laminated and then extruded through T-shaped dies with set temperature of 260° C. The obtained film-shaped substance was molded by being sandwiched between a pair of metal rolls, thereby preparing a base material film (PMMA/PC/PMMA) which had a total thickness of 200 μm and constituted with three layers of acrylic resin layer/polycarbonate-based resin layer/acrylic resin layer.

### Example 31

A hardcoat film (a front plate of an image display element) of Example 31 was prepared by the same method as in Example 30, except that the total thickness of the base material constituted with three layers was changed to 100 μm.

### Example 32

A hardcoat film (a front plate of an image display element) of Example 32 was prepared by the same method as in Example 30, except that as a base material film, a three-layered (layer I/layer II/layer III) polyester-based resin laminated film prepared by the following method was used.

<Three-Layered Polyester-Based Resin Laminated Film>

According to paragraphs “0181” to “0188” in JP2014-182274A, raw material polyester 1 (PET 1) was prepared.

According to Example 1 in paragraph “0189” in JP2014-182274A, 90 parts by mass of the raw material polyester 1 and 10 parts by mass of an ultraviolet absorber (2,2′-(1,4-phenylene)bis(4H-3,1-benzoxazin-4-one) were mixed together. Then, by using a kneading extruder, raw material polyester 2 (PET 2) containing an ultraviolet absorber was prepared.

90 parts by mass of the raw material polyester 1 (PET 1) and 10 parts by mass of the raw material polyester 2 (PET 2) containing an ultraviolet absorber were dried until the moisture content thereof became equal to or lower than 20 ppm by mass. Then, the polyesters were put into a hopper of a first single-screw kneading extruder having a diameter of 50 mm and melted at 300° C. in the first single-screw kneading extruder, thereby preparing a molten resin material for forming the layer II positioned between the layer I and the layer II.

The raw material polyester 1 was dried until the moisture content thereof became equal to or lower than 20 ppm by mass, then put into a hopper of a second single-screw kneading extruder having a diameter of 30 mm, and melted at 300° C. in the second single-screw kneading extruder, thereby preparing a resin composition for forming the layer I and the layer III.

These two kinds of molten resin materials were respectively passed through a gear pump and a filter (pore size: 20 μm). Then, through a block by which the two kinds of resins become confluent as three layers, the resin materials were laminated such that the molten resin extruded from the first single-screw extruder became the internal layer (layer II) and that the molten resin material extruded from the second single-screw extruder became the outer layers (layer I and layer III), and then extruded in the form of a sheet from a die having a width of 120 mm.

The molten resin sheet extruded from the die was disposed onto a cooling cast drum set to be at a temperature of 25° C. and caused to come into close contact with the cooling cast drum by using a method of applying static electricity. By using a peeling roll disposed to face the cooling cast drum, the resin sheet was peeled, thereby obtaining a non-stretched film. At this time, the amount of resin discharged from each extruder was adjusted such that a thickness ratio of layer I:layer II:layer III became 10:80:10.

By using a group of heated rolls and an infrared heater, the non-stretched film was heated such that the surface temperature of the film became 95° C. Then, by using a group of rolls having different circumferential speeds, the film was stretched in the movement direction of the film by a factor of 3.1, thereby obtaining a three-layered polyester-based resin laminated film.

### Example 33

A hardcoat film (a front plate of an image display element) of Example 33 was prepared by the same method as in Example 1, except that as a base material film, an acryl/polycarbonate multilayered film (manufactured by Escarbo Sheet Company, Ltd, trade name “TECHNOLLOY C001”, film thickness: 300 μm) in which a polycarbonate layer and a PMMA layer were laminated was used instead of TECHNOLLOY C101, and that the cured layer was disposed on the PMMA layer side.

### Example 34

A hardcoat film (a front plate of an image display element) of Example 34 was prepared by the same method as in Example 1, except that as a base material film, TAC-1 prepared as below was used instead of TECHNOLLOY C101.

<1. Preparation of Resin Film>

(1) Preparation of Cellulose Acylate Dope Solution for Core Layer

The following composition was put into a mixing tank and stirred, thereby preparing a cellulose acylate dope solution for a core layer.

Cellulose acylate dope solution for core layer

| | | |
|---|---|---|
| Cellulose acetate with a degree of acetyl | 100 | parts by mass |
| substitution of 2.88 and a weight-average | | |
| molecular weight of 260,000 | | |
| Phthalic acid ester oligomer A having the | 10 | parts by mass |
| following structure | | |
| Compound (C-1) represented by Formula I | 4 | parts by mass |
| Ultraviolet absorber represented by Formula II | 2.7 | parts by mass |
| (manufactured by BASF SE) | | |
| Light stabilizer (manufactured by BASF SE, trade | 0.18 | parts by mass |
| name: TINUVIN 123) | | |
| N-alkenylpropylenediamine tetraacetic acid | 0.02 | parts by mass |
| (manufactured by Nagase ChemteX Corporation, | | |
| trade name: TEKURAN DO) | | |
| Methylene chloride (first solvent) | 430 | parts by mass |
| Methanol (second solvent) | 64 | parts by mass |

The used compounds will be shown below.

Phthalic acid ester oligomer A (weight-average molecular weight: 750)

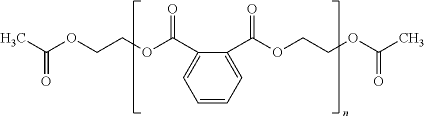

Compound (C-1) represented by Formula I

Formula I:

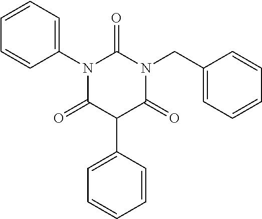 [SMILES: O=C1C(c2ccccc2)C(=O)N(c2ccccc2)C(=O)N1Cc1ccccc1]

Ultraviolet absorber represented by Formula II

Formula II:

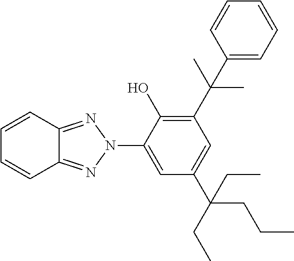 [SMILES: CCCC(CC)(CC)c1cc(-n2nc3ccccc3n2)c(O)c(C(C)(C)c2ccccc2)c1]

(2) Preparation of Cellulose Acylate Dope Solution for Outer Layer

10 parts by mass of a composition containing inorganic fine particles shown below was added to 90 parts by mass of the aforementioned cellulose acylate dope solution for a core layer, thereby preparing a cellulose acylate, dope solution for an outer layer

Composition containing inorganic fine particles

| | |
|---|---|
| Silica particles having an average primary particle | 2 parts by mass |
| diameter of 20 nm (manufactured by NIPPON | |
| AEROSIL CO., LTD, trade name: AEROSIL R972) | |
| Methylene chloride (first solvent) | 76 parts by mass |
| Methanol (second solvent) | 11 parts by mass |
| Cellulose acylate dope solution for core layer | 1 part by mass |

(3) Preparation of Resin Film (TAC-1)

In order for the cellulose acylate dope solution for an outer layer to be positioned on both sides of the cellulose acylate dope solution for a core layer, three kinds of solutions including the cellulose acylate dope solution for an outer layer, the cellulose acylate dope solution for a core layer, and the cellulose acylate dope solution for an outer layer were simultaneously cast onto a casting band with a surface temperature of 20° C. from a casting outlet.

As the casting band, an endless band was used which was made of stainless steel and had a width of 2.1 m and a length of 70 m. The casting band was polished such that it had a thickness of 1.5 mm and a surface roughness equal to or smaller than 0.05 μm. The material of the casting band was SUS 316 and had sufficient corrosion resistance and hardness. The thickness unevenness of the entirety of the casting band was equal to or lower than 0.5%.

The surface of the obtained casting film was exposed to the air for fast drying with a gas concentration of 16% and a temperature of 60° C. at a wind speed of 8 m/s, thereby forming an initial film. Then, drying air with a temperature of 140° C. was blown to the film from the upstream side of the upper portion of the casting band. Furthermore, drying air with a temperature of 120° C. and drying air with a temperature of 60° C. were blown to the film from the downstream side.

After the amount of residual solvent became about 33% by mass, the film was peeled off from the band. Then, both ends of the obtained film in the width direction were fixed to tenter clips, and after the amount of residual solvent became 3% to 15% by mass, the film was dried while being stretched in the width direction by a factor of 1.06. Thereafter, the film was transported between rolls of a heat treatment device and then further dried, thereby preparing a resin film (TAC-1) having a thickness of 100 μm (outer layer/core layer/outer layer=3 μm/94 μm/3 μm).

[Evaluation]

<Pencil Hardness>

For the base material film of the hardcoat film (the front plate of an image display element) of each of the examples, comparative examples, and reference examples, the surface of the base material film on which the cured layer was disposed was evaluated in terms of pencil hardness according to Japanese Industrial Standards (JIS) K 5400.

The hardcoat film of each of the examples, the comparative examples, and the reference examples was humidified for 2 hours at a temperature of 25° C. and a relative humidity of 60%%, and then 5 different sites on the surface to be evaluated were scratched under a load of 4.9 N by using a testing pencil with hardness of H to 9H specified in JIS S 6006. The hardness of the pencil (pencil with the highest hardness) by which visually recognized scratch was formed at 0 to 2 sites at this time was taken as pencil hardness. The obtained results are described in the following Tables 4 and 5.

<Surface Roughness>

For the base material film of the hardcoat film of each of the examples, the comparative examples, and the reference examples, the surface of the base material film on which the cured layer was disposed was evaluated in terms of an arithmetic average roughness (Ra) of the surface roughness.

The arithmetic average roughness (Ra) of the surface roughness of the hardcoat film of each of the examples, the comparative examples, and the reference examples was set according to JIS B-0601 (2001) by using a stylus-type surface roughness measuring instrument “SURFCORDER SE3500” {manufactured by Kosaka Laboratory Ltd.}, and the value measured using the stylus-type surface roughness measuring instrument was adopted. The obtained results are described in the following Tables 4 and 5.

In the present invention, a hardcoat film having an arithmetic average roughness (Ra) of the surface roughness of equal to or greater than 0.08 μm was regarded as sufficiently expressing surface asperities.

TABLE 4

| | | Cured layer | | | | | |
|---|---|---|---|---|---|---|---|
| | | Active energy | | Polyrotaxane or other polymers | | | |
| | Base material film | ray-curable | Film thickness | | | Unsaturated double | Weight-average |
| | Type | resin composition | [μm] | Type | Content | bond group | molecular weight |
| Example 1 | TECHNOLLOY C101 | HC1 | 30 | PR1 | 20 wt % | Methacryloyl group | 180,000 |
| Example 2 | TECHNOLLOY C101 | HC1 | 20 | PR1 | 20 wt % | Methacryloyl group | 180,000 |
| Example 3 | TECHNOLLOY C101 | HC1 | 12 | PR1 | 20 wt % | Methacryloyl group | 180,000 |
| Example 4 | TECHNOLLOY C101 | HC1 | 40 | PR1 | 20 wt % | Methacryloyl group | 180,000 |
| Example 5 | TECHNOLLOY C101 | HC1 | 60 | PR1 | 20 wt % | Methacryloyl group | 180,000 |
| Example 6 | TECHNOLLOY C101 | HC2 | 30 | PR1 | 20 wt % | Methacryloyl group | 180,000 |
| Example 7 | TECHNOLLOY C101 | HC3 | 30 | PR1 | 20 wt % | Methacryloyl group | 180,000 |
| Example 8 | TECHNOLLOY C101 | HC4 | 30 | PR1 | 20 wt % | Methacryloyl group | 180,000 |
| Example 9 | TECHNOLLOY C101 | HC5 | 30 | PR1 | 20 wt % | Methacryloyl group | 180,000 |
| Example 10 | TECHNOLLOY C101 | HC6 | 30 | PR1 | 1 wt % | Methacryloyl group | 180,000 |
| Example 11 | TECHNOLLOY C101 | HC7 | 30 | PR1 | 5 wt % | Methacryloyl group | 180,000 |
| Example 12 | TECHNOLLOY C101 | HC8 | 30 | PR1 | 10 wt % | Methacryloyl group | 180,000 |
| Example 13 | TECHNOLLOY C101 | HC9 | 30 | PR1 | 30 wt % | Methacryloyl group | 180,000 |
| Example 14 | TECHNOLLOY C101 | HC10 | 30 | PR1 | 40 wt % | Methacryloyl group | 180,000 |
| Example 15 | TECHNOLLOY C101 | HC11 | 30 | PR1 | 20 wt % | Methacryloyl group | 180,000 |
| Example 16 | TECHNOLLOY C101 | HC12 | 30 | PR1 | 20 wt % | Methacryloyl group | 180,000 |
| Example 17 | TECHNOLLOY C101 | HC13 | 30 | PR1 | 20 wt % | Methacryloyl group | 180,000 |
| Example 18 | TECHNOLLOY C101 | HC14 | 30 | PR1 | 20 wt % | Methacryloyl group | 180,000 |

| | Cured layer | | | | | |
|---|---|---|---|---|---|---|
| | Matt particles | | | | | |
| | | Mass of matt | Inorganic fine particles | | | |
| | Average | particles | Average | | Evaluation | |
| | primary | contained in | primary | | | Surface |
| | particle | cured layer | particle | | Pencil | roughness |
| | diameter | [g/cm³] | diameter | Content | hardness | Ra [μm] |
| Example 1 | 6 μm | 0.16 | 15 nm | 15 wt % | 8H | 0.64 |
| Example 2 | 6 μm | 0.16 | 15 nm | 15 wt % | 7H | 0.96 |
| Example 3 | 6 μm | 0.16 | 15 nm | 15 wt % | 5H | 1.32 |
| Example 4 | 6 μm | 0.16 | 15 nm | 15 wt % | 9H | 0.57 |
| Example 5 | 6 μm | 0.16 | 15 nm | 15 wt % | 9H | 0.14 |
| Example 6 | 6 μm | 0.11 | 15 nm | 15 wt % | 8H | 0.09 |
| Example 7 | 6 μm | 0.21 | 15 nm | 15 wt % | 8H | 0.96 |
| Example 8 | 6 μm | 0.32 | 15 nm | 15 wt % | 7H | 1.21 |
| Example 9 | 6 μm | 0.42 | 15 nm | 15 wt % | 5H | 1.39 |
| Example 10 | 6 μm | 0.16 | 15 nm | 15 wt % | 8H | 0.11 |
| Example 11 | 6 μm | 0.16 | 15 nm | 15 wt % | 8H | 0.25 |
| Example 12 | 6 μm | 0.16 | 15 nm | 15 wt % | 8H | 0.44 |
| Example 13 | 6 μm | 0.16 | 15 nm | 15 wt % | 7H | 0.97 |
| Example 14 | 6 μm | 0.16 | 15 nm | 15 wt % | 6H | 1.13 |
| Example 15 | 2 μm | 0.16 | 15 nm | 15 wt % | 8H | 0.13 |
| Example 16 | 4 μm | 0.16 | 15 nm | 15 wt % | 8H | 0.27 |
| Example 17 | 10 μm | 0.16 | 15 nm | 15 wt % | 8H | 0.82 |
| Example 18 | 14 μm | 0.16 | 15 nm | 15 wt % | 8H | 1.21 |

TABLE 5

| | | Cured layer | | | | | |
|---|---|---|---|---|---|---|---|
| | | Active energy | | Polyrotaxane or other polymers | | | |
| | Base material film | ray-curable | Film thickness | | | Unsaturated double | Weight-average |
| | Type | resin composition | [μm] | Type | Content | bond group | molecular weight |
| Example 19 | TECHNOLLOY C101 | HC15 | 30 | PR1 | 20 wt % | Methacryloyl group | 180,000 |
| Example 20 | TECHNOLLOY C101 | HC16 | 30 | PR1 | 20 wt % | Methacryloyl group | 180,000 |
| Example 21 | TECHNOLLOY C101 | HC17 | 30 | PR1 | 20 wt % | Methacryloyl group | 180,000 |
| Example 22 | TECHNOLLOY C101 | HC18 | 30 | PR1 | 20 wt % | Methacryloyl group | 180,000 |
| Example 23 | TECHNOLLOY C101 | HC19 | 30 | PR1 | 20 wt % | Methacryloyl group | 180,000 |
| Example 24 | TECHNOLLOY C101 | HC20 | 30 | PR1 | 20 wt % | Methacryloyl group | 180,000 |
| Example 25 | TECHNOLLOY C101 | HC21 | 30 | PR2 | 20 wt % | Absent | 180,000 |
| Example 26 | TECHNOLLOY C101 | HC22 | 30 | PR3 | 20 wt % | Acryloyl group | 180,000 |
| Example 27 | TECHNOLLOY C101 | HC23 | 30 | PR4 | 20 wt % | Methacryloyl group | 1,000,000 |
| Example 28 | TECHNOLLOY C101 | HC1 | 30 | PR1 | 20 wt % | Methacryloyl group | 180,000 |
| Example 29 | TECHNOLLOY C101 | HC1 | 30 | PR1 | 20 wt % | Methacryloyl group | 180,000 |
| Example 30 | PMMA/PC/PMMA | HC1 | 30 | PR1 | 20 wt % | Methacryloyl group | 180,000 |
| Example 31 | PMMA/PC/PMMA | HC1 | 30 | PR1 | 20 wt % | Methacryloyl group | 180,000 |
| Example 32 | Polyester-based resin | HC1 | 30 | PR1 | 20 wt % | Methacryloyl group | 180,000 |
| | layer | | | | | | |
| Example 33 | TECHNOLLOY C101 | HC1 | 30 | PR1 | 20 wt % | Methacryloyl group | 180,000 |
| Example 34 | TAC-1 | HC1 | 30 | PR1 | 20 wt % | Methacryloyl group | 180,000 |
| Comparative | TECHNOLLOY C101 | HC24 | 30 | — | — | — | — |
| Example 1 | | | | | | | |
| Comparative | TECHNOLLOY C101 | HC25 | 30 | Polyester | 20 wt % | — | 400,000 |
| Example 2 | | | | urethane | | | |
| Comparative | TECHNOLLOY C101 | HC26 | 30 | PR1 | 20 wt % | Methacryloyl group | 180,000 |
| Example 3 | | | | | | | |
| Reference | TECHNOLLOY C101 | HC24 | 10 | — | — | — | — |
| Example 1 | | | | | | | |
| Reference | TECHNOLLOY C101 | HC27 | 30 | — | — | — | — |
| Example 2 | | | | | | | |

| | Cured layer | | | | | |
|---|---|---|---|---|---|---|
| | Matt particles | | | | | |
| | | Mass of matt | Inorganic fine particles | | | |
| | Average | particles | Average | | Evaluation | |
| | primary | contained in | primary | | | Surface |
| | particle | cured layer | particle | | Pencil | roughness |
| | diameter | [g/cm³] | diameter | Content | hardness | Ra [μm] |
| Example 19 | 20 μm | 0.16 | 15 nm | 15 wt % | 8H | 1.48 |
| Example 20 | 6 μm | 0.16 | 45 nm | 15 wt % | 8H | 0.64 |
| Example 21 | 6 μm | 0.16 | 85 nm | 15 wt % | 7H | 0.64 |
| Example 22 | 6 μm | 0.16 | 15 nm | 5 wt % | 7H | 0.64 |
| Example 23 | 6 μm | 0.16 | 15 nm | 30 wt % | 8H | 0.64 |
| Example 24 | 6 μm | 0.16 | 15 nm | 40 wt % | 7H | 0.64 |
| Example 25 | 6 μm | 0.16 | 15 nm | 15 wt % | 7H | 0.64 |
| Example 26 | 6 μm | 0.16 | 15 nm | 15 wt % | 7H | 0.64 |
| Example 27 | 6 μm | 0.16 | 15 nm | 15 wt % | 7H | 0.64 |
| Example 28 | 6 μm | 0.16 | 15 nm | 15 wt % | 8H | 0.64 |
| Example 29 | 6 μm | 0.16 | 15 nm | 15 wt % | 8H | 0.64 |
| Example 30 | 6 μm | 0.16 | 15 nm | 15 wt % | 7H | 0.64 |
| Example 31 | 6 μm | 0.16 | 15 nm | 15 wt % | 6H | 0.64 |
| Example 32 | 6 μm | 0.16 | 15 nm | 15 wt % | 8H | 0.64 |
| Example 33 | 6 μm | 0.16 | 15 nm | 15 wt % | 8H | 0.64 |
| Example 34 | 6 μm | 0.16 | 15 nm | 15 wt % | 8H | 0.64 |
| Comparative | 6 μm | 0.16 | 15 nm | 15 wt % | 8H | 0.02 |
| Example 1 | | | | | | |
| Comparative | 6 μm | 0.16 | 15 nm | 15 wt % | 8H | 0.02 |
| Example 2 | | | | | | |
| Comparative | 1.5 μm | 0.16 | 15 nm | 15 wt % | 8H | 0.02 |
| Example 3 | | | | | | |
| Reference | 6 μm | 0.16 | 15 nm | 15 wt % | 4H | 1.58 |
| Example 1 | | | | | | |
| Reference | 6 μm | 0.16 | — | — | 4H | 0.12 |
| Example 2 | | | | | | |

From the above Tables 4 and 5, it was understood that in the hardcoat film of the present invention, both the high surface hardness and the sufficient surface asperities can be achieved in the cured layer which contains inorganic fine particles and has a large film thickness. From Examples 2 and 3, it was understood that although the surface hardness is reduced as the film thickness of the cured layer is decreased, the surface asperities can be increased. From Examples 4 and 5, it was understood that although the surface hardness is increased as the film thickness of the cured layer is increased, the surface asperities are reduced. From Example 6, it was understood that in a case where the mass of the matt particles contained in the cured layer is reduced, the surface asperities are reduced. From Examples 7 to 9, it was understood that in a case where the mass of the matt particles contained in the cured layer is increased, the surface asperities can be increased, but in a case where the mass of the matt particles contained in the cured layer is increased too much, the surface hardness is reduced. From Examples 10 to 12, it was understood that in a case where the amount of polyrotaxane in the cured layer is reduced, the surface asperities are reduced. From Examples 13 and 14, it was understood that in a case where the amount of polyrotaxane in the cured layer is increased too much, the surface hardness is reduced, and the surface asperities are also reduced. From Examples 15 and 16, it was understood that the smaller the average primary particle diameter of the matt particles, the smaller the surface asperities. In contrast, from Examples 17 to 19, it was understood that there is no problem even though the average primary particle diameter of the matt particles are increased to a certain extent. From Examples 20 and 21, it was understood that in a case where the average primary particle diameter of the inorganic fine particles is too large, the surface hardness is reduced. From Example 22, it was understood that the smaller the inorganic fine particles in the cured layer, the lower the surface hardness. From Examples 23 and 24, it was understood that in a case where the cured layer contains the inorganic fine particles too much, the surface hardness is reduced. From Example 25, it was understood that in a case where the polyrotaxane does not have an unsaturated double bond group, the surface hardness is seriously reduced. From Example 26, it was understood that in a case where the polyrotaxane has an acryloyl group as an unsaturated double bond group, the surface hardness is reduced. From Example 27, it was understood that in a case where the molecular weight of the polyrotaxane is equal to or greater than 1,000,000, the surface hardness is reduced. From Examples 28 and 29, it was understood that in an aspect of bonding a touch sensor film or in an aspect of providing a layer of low refractive index, the effects of the present invention are also obtained. From Examples 30 and 31, it was understood that in a case where the film thickness of the base material film is reduced, the surface hardness is also reduced. From Examples 32 to 34, it was understood that there is no problem even though the material of the base material film is changed.

From Comparative Example 1 in which the cured layer did not contain polyrotaxane, it was understood that in a case where the pencil hardness is increased by increasing the film thickness of the cured layer and adding the inorganic fine particles, simply by adding, the matt particles, the surface asperities are not sufficiently expressed.

From the Comparative Example 2 in which polyester urethane having self-restoring properties was used instead of polyrotaxane in the cured layer, it was understood that in a case where the pencil hardness is increased by increasing the film thickness of the cured layer and adding the inorganic fine particles, simply by adding the matt particles, the surface asperities are not sufficiently expressed. Herein, in a case where the polyester urethane in Comparative Example 2 was added, the hardcoat film turned white.

From Comparative Example 3 in which the average primary particle diameter of the matt particles was smaller than 2 μm, it was understood that in a case where the pencil hardness is increased by increasing the film thickness of the cured layer and adding the inorganic fine particles, even though polyrotaxane was added, the surface asperities are not sufficiently expressed.

From Reference Example 1, it was understood that as long as the film thickness of the cured layer is equal to or less than 10 μm, in a case where the pencil hardness is increased by adding the inorganic fine particles, the surface asperities can be sufficiently expressed simply by adding the matt particles even though polyrotaxane is not added, but the pencil hardness becomes insufficient.

From Reference Example 2, it was understood that in a case where the cured layer does not contain the inorganic fine particles, when the film thickness of the cured layer is increased, the surface asperities can be sufficiently expressed simply by adding the matt particles even though polyrotaxane is not added, but the pencil hardness becomes insufficient.

### Examples 101 to 134

<Bonding to Polarizer>

Onto one surface of a polarizer, which was prepared by causing iodine to be adsorbed onto polyvinyl alcohol and stretching the resultant, a triacetyl cellulose film (TAC-TD80U, manufactured by FUJIFILM Corporation) having a thickness of 80 μm was bonded which was immersed for 2 minutes in a 1.5 mol/L aqueous NaOH solution with a temperature of 55° C. and then neutralized and washed with water. Onto the other surface of the polarizer, a surface of the hardcoat film of each of Examples 1 to 34 that was opposite to a surface of the hardcoat film on which the cured layer was disposed was bonded, thereby preparing hardcoat films of Examples 101 to 134 integrated with the polarizing plate. In this way, the hardcoat film of the present invention can be applied to a polarizing plate.

<Preparation of Image Display with Touch Panel>

Onto the color filter integrated with a touch panel sensor described in paragraphs “0139” to “0143” in JP2012-88683A, the hardcoat film (capacitance-type touch panel) of Example 28 bonded to a touch sensor film was bonded, thereby preparing an image display of Example 228 including a touch panel. It was understood that because the image display of Example 228 including a touch panel has high pencil hardness on the surface thereof and sufficiently expresses surface asperities, the image display gives an excellent feeling of writing (for example, sliding properties at the time of performing writing by using a stylus) in a case where input is performed in the touch panel by using a stylus.

What is claimed is:

1. A hardcoat film comprising:
a base material film; and
a cured layer disposed on at least one surface of the base material film,
wherein the cured layer is obtained by curing an active energy ray-curable resin composition,
a film thickness of the cured layer is greater than 10 μm,
the cured layer contains polyrotaxane, inorganic fine particles having an average primary particle diameter of less than 2 μm, and matt particles having an average primary particle diameter of equal to or greater than 2 μm, and
a mass of the matt particles contained in the cured layer is equal to or greater than 0.10 g/cm³.

2. The hardcoat film according to claim 1,
wherein the film thickness of the cured layer is greater than 10 μm and equal to or smaller than 60 μm.

3. The hardcoat film according to claim 1,
wherein the polyrotaxane has an unsaturated double bond group.

4. The hardcoat film according to claim 3,
wherein the unsaturated double bond group is a methacryloyl group.

5. The hardcoat film according to claim 1,
wherein a weight-average molecular weight of the polyrotaxane is equal to or smaller than 600,000.

6. The hardcoat film according to claim 1,
wherein the matt particles are organic resin particles.

7. The hardcoat film according to claim 1, further comprising:
a layer of low refractive index on the cured layer directly or through another layer.

8. The hardcoat film according to claim 1,
wherein the base material film is a laminated film having at least one layer of acrylic resin film and at least one layer of polycarbonate-based resin film.

9. The hardcoat film according to claim 1,
wherein the base material film is a cellulose acylate film.

10. The hardcoat film according to claim 1,
wherein a film thickness of the base material film is equal to or greater than 100 μm.

11. The hardcoat film according to claim 1, further comprising:
a touch sensor film on a surface of the base material film that is opposite to a surface of the base material film on which the cured layer is disposed.

12. The hardcoat film according to claim 1, further comprising:
a polarizer on a surface of the base material film that is opposite to a surface of the base material film on which the cured layer is disposed.

13. The hardcoat film according to claim 1 that is a hardcoat film for a front plate of a touch panel.

14. A front plate of an image display element, comprising:
the hardcoat film according to claim 1.

15. A resistive film-type touch panel comprising:
the front plate of an image display element according to claim 14.

16. A capacitance-type touch panel comprising:
the front plate of an image display element according to claim 14.

17. An image display comprising;
the front plate of an image display element according to claim 14; and
an image display element.

18. The image display according to claim 17,
wherein the image display element is a liquid crystal display element.

19. The image display according to claim 17,
wherein the image display element is an organic electroluminescence display element.

20. The image display according to claim 17,
wherein the image display element is an in-cell touch panel display element.

21. The image display according to claim 17,
wherein the image display is an on-cell touch panel display element.
